(19) United States
(12) Patent Application Publication
(10) Pub. No.: US 2011/0006846 A1
(43) Pub. Date: Jan. 13, 2011

(54) HIGH-FREQUENCY AMPLIFIER

(75) Inventors: Satoshi Miho, Tokyo (JP); Hifumi Noto, Tokyo (JP); Kazutomi Mori, Tokyo (JP); Eri Teranishi, Tokyo (JP); Akira Inoue, Tokyo (JP)

Correspondence Address: OBLON, SPIVAK, MCCLELLAND MAIER & NEUSTADT, L.L.P., 1940 DUKE STREET, ALEXANDRIA, VA, 22314, US

(73) Assignee: Mitsubishi Electric Corporation, Tokyo (JP)

(21) Appl. No.: 12/919,492

(22) PCT Filed: Apr. 1, 2009
(86) PCT No.: PCT/JP2009/001527

§ 371 Date: Aug. 26, 2010

(30) Foreign Application Priority Data
Apr. 8, 2008 (JP) 2008-100538
Jul. 15, 2008 (JP) 2008-183646

(51) Int. Cl. H03G 3/30

(52) U.S. Cl. 330/278

(57) ABSTRACT

A high-frequency amplifier is configured in such a manner that a detecting diode 4 and an NPN bipolar transistor 11 of a bias circuit 5 are biased by a common power supply, and that when the amplitude of an envelope signal increases, the bias current supplied from the NPN bipolar transistor 11 to an amplifying element 15 is suppressed following the amplitude of the envelope signal.

### TECHNICAL FIELD

The present invention relates to a high-frequency amplifier used for satellite communications, terrestrial microwave communications, mobile communications and the like, for example.

### BACKGROUND ART

Generally, as for a high-frequency amplifier used for mobile communications and the like, higher efficiency and lower distortion are required in a wide range of its output level.

As a technique of achieving higher efficiency over the wide range of the output level, a method has been known which controls the bias supplied to the high-frequency amplifier in accordance with the input level or output level.

However, to improve the efficiency, the bias supplied to the high-frequency amplifier must be changed from class A operation with high linearity to class B or class AB operation with high efficiency. In contrast, to achieve low distortion, the bias supplied to the high-frequency amplifier must be changed from the class B or class AB operation with high efficiency to the class A operation with high linearity. Thus, the method of improving the efficiency and the method of achieving the low distortion conflict with each other.

On the other hand, accompanying an increase of communication capacitance and communication speed, orthogonal frequency division multiplexing (OFDM) and the like has been used.

However, an OFDM modulation wave according to the orthogonal frequency division multiplexing has a drawback of having a large crest factor (ratio between a peak value of the waveform and an effective value).

Accordingly, when amplifying such a microwave signal, unless the amplifier is operated in a condition with sufficiently large back off, which is defined as the difference between average power and saturation power at its actual operation, the peak value of the waveform can sometimes become dull and bring about signal distortion.

FIG. 25 is a diagram showing a configuration of a conventional high-frequency amplifier disclosed in the following Patent Document 1.

FIG. 25 shows an example that achieves high efficiency and low distortion in a high-frequency amplifier with gain characteristics that bend upward.

In FIG. 25, an input terminal 201 is a terminal to which a high-frequency signal is supplied, and a detector circuit 202 is a circuit for detecting the amplitude of the high-frequency signal input via the input terminal 201.

The detector circuit 202 comprises a DC blocking capacitance 202a, an NPN bipolar transistor 202b, a bias resistance 202c and a power supply 202d.

A bias circuit 203 is a circuit for supplying a base terminal of an amplifying element 205 with a bias current corresponding to the amplitude of the high-frequency signal detected with the detector circuit 202 via a bias inductor 204.

The bias circuit 203 comprises a constant current source 203a, a power supply 203b, a bias resistance 203c and NPN bipolar transistors 203d and 203e.

The amplifying element 205 is a component that has its gain characteristics controlled in response to the bias current supplied from the bias circuit 203, and amplifies the high-frequency signal input via the input terminal 201.

An output terminal 206 is a terminal that outputs the high-frequency signal amplified with the amplifying element 205.

Next, the operation will be described.

When the high-frequency signal is input via the input terminal 201, the amplifying element 205 amplifies the high-frequency signal, and outputs the amplified high-frequency signal from the output terminal 206.

On this occasion, the detector circuit 202 detects the amplitude of the high-frequency signal input via the input terminal 201.

More specifically, the NPN bipolar transistor 202b of the detector circuit 202 operates when supplied with the base voltage from the power supply 202d via the bias resistance 202c, and outputs, when the high-frequency signal is input via the input terminal 201, a collector current corresponding to the amplitude of the high-frequency signal (collector current that increases in accordance with the amplitude of the high-frequency signal) to the bias circuit 203.

When the detector circuit 202 detects the amplitude of the high-frequency signal, the bias circuit 203 supplies the bias current corresponding to the amplitude of the high-frequency signal to the base terminal of the amplifying element 205.

Thus, when the amplitude of the high-frequency signal increases, and hence the collector current output from the detector circuit 202 increases, the bias circuit 203 operates in such a manner as to decrease the bias current supplied to the base terminal of the amplifying element 205.

More specifically, the bias current supplied to the base terminal of the amplifying element 205 is generated when the constant current source 203a supplies currents to the collector terminal of the NPN bipolar transistor 203d and to the base terminal of the NPN bipolar transistor 203e. When the high-frequency signal is input via the input terminal 201 and the bias circuit 203 receives the collector current from the NPN bipolar transistor 202b of the detector circuit 202, the current supplied from the constant current source 203a decreases by the amount of the collector current. Thus, the bias current supplied to the base terminal of the amplifying element 205 reduces.

Patent Document 1: Japanese Patent Laid-Open No. 2003-273660 (Paragraphs [0019] and [0020], and FIG. 1)

With the foregoing configuration, the conventional high-frequency amplifier reduces the bias current supplied to the base terminal of the amplifying element 205 when the high-frequency signal input via the input terminal 201 increases. In this way, it can achieve flat gain characteristics and high linearity even at the high output power. In addition, the bias circuit 203 supplies the base terminal of the amplifying element 205 with the bias current corresponding to the amplitude of the high-frequency signal detected by the detector circuit 202. Accordingly, it can maintain the linearity when the amplifying element 205 has gain characteristics that bend upward in the low idle current operation. However, since the DC blocking capacitance 202a is connected to the detector circuit 202, it has a problem of being unable to follow the modulation speed of the high-frequency signal which is a modulation wave.

Furthermore, since the detector circuit 202 must include the power supply 202d, it has a problem of reducing its efficiency because of newly added power consumption.

Moreover, since the gain close to the saturation reduces when the modulation wave signal with a high crest factor is input via the input terminal 201, it has a problem of deteriorating the distortion characteristics.

The present invention is implemented to solve the foregoing problems. Therefore it is an object of the present invention to provide a high-frequency amplifier capable of following the modulation speed of the modulation wave by obviating the need for the power supply and the DC blocking capacitance of the detector circuit, and capable of preventing the deterioration of the distortion characteristics involved in the gain reduction close to the saturation even if the modulation wave signal with the high crest factor is input.

### DISCLOSURE OF THE INVENTION

A high-frequency amplifier in accordance with the present invention is configured in such a manner as to bias a detecting unit and a bias current supplying unit with a common power supply, and to increase or decrease the bias current supplied from the bias current supplying unit to an amplifying unit in accordance with the amplitude of an envelope signal when the amplitude of the envelope signal becomes large.

In this way, it offers advantages of being able to follow the modulation speed of the modulation wave by obviating the need for the power supply and the DC blocking capacitance of the detector circuit, and to prevent the deterioration of the distortion characteristics involved in the gain reduction near the saturation even when the modulation wave signal with the high crest factor is input.

### BRIEF DESCRIPTION OF THE DRAWINGS

FIG. 1 is a diagram showing a configuration of a high-frequency amplifier of an embodiment 1 in accordance with the present invention;

FIG. 2 is a diagram showing distortion characteristics and gain characteristics of the high-frequency amplifier of the embodiment 1 in accordance with the present invention;

FIG. 3 is a diagram showing another configuration of the high-frequency amplifier of the embodiment 1 in accordance with the present invention;

FIG. 4 is a diagram showing a configuration of a high-frequency amplifier of an embodiment 2 in accordance with the present invention;

FIG. 5 is a diagram showing distortion characteristics and gain characteristics of the high-frequency amplifier of the embodiment 2 in accordance with the present invention;

FIG. 6 is a diagram showing a configuration of a high-frequency amplifier of an embodiment 3 in accordance with the present invention;

FIG. 7 is a diagram showing a configuration of a high-frequency amplifier of an embodiment 4 in accordance with the present invention;

FIG. 8 is a diagram showing a configuration of a high-frequency amplifier of an embodiment 5 in accordance with the present invention;

FIG. 9 is a diagram showing a configuration of a high-frequency amplifier of an embodiment 6 in accordance with the present invention;

FIG. 10 is a diagram showing distortion characteristics and gain characteristics of the high-frequency amplifier of the embodiment 6 in accordance with the present invention;

FIG. 11 is a diagram showing a configuration of a high-frequency amplifier of an embodiment 7 in accordance with the present invention;

FIG. 12 is a diagram showing a configuration of a high-frequency amplifier of an embodiment 8 in accordance with the present invention;

FIG. 13 is a diagram showing a configuration of a high-frequency amplifier of an embodiment 9 in accordance with the present invention;

FIG. 14 is a diagram showing a configuration of a high-frequency amplifier of an embodiment 10 in accordance with the present invention;

FIG. 15 is a diagram showing a configuration of a high-frequency amplifier of an embodiment 11 in accordance with the present invention;

FIG. 16 is a diagram showing a configuration of a multistage amplifier having a plurality of high-frequency amplifiers of any of the embodiments 1-11 connected in multistage;

FIG. 17 is a diagram showing a configuration of a high-frequency amplifier having an analog linearizer connected at a pre-stage;

FIG. 18 is a diagram showing a configuration of a high-frequency amplifier having a multistage amplifier connected at a pre-stage;

FIG. 19 is a diagram showing a configuration of a high-frequency amplifier of an embodiment 15 in accordance with the present invention;

FIG. 20 is a diagram showing a configuration of a bias control circuit of the high-frequency amplifier of the embodiment 15 in accordance with the present invention;

FIG. 21 is a diagram showing the amplitude of an envelope signal, control voltages Vout_m and Vout_p output from a differential amplifier, and gains Gain _m and Gain_p of an amplifying element;

FIG. 22 is a diagram showing a configuration of a high-frequency amplifier of an embodiment 16 in accordance with the present invention;

FIG. 23 is a diagram showing a configuration of a high-frequency amplifier of an embodiment 17 in accordance with the present invention;

FIG. 24 is a diagram showing a configuration of a high-frequency amplifier of an embodiment 18 in accordance with the present invention; and

FIG. 25 is a diagram showing a configuration of a conventional high-frequency amplifier.

### BEST MODE FOR CARRYING OUT THE INVENTION

The best mode for carrying out the invention will now be described with reference to the accompanying drawings to explain the present invention in more detail.

### EMBODIMENT 1

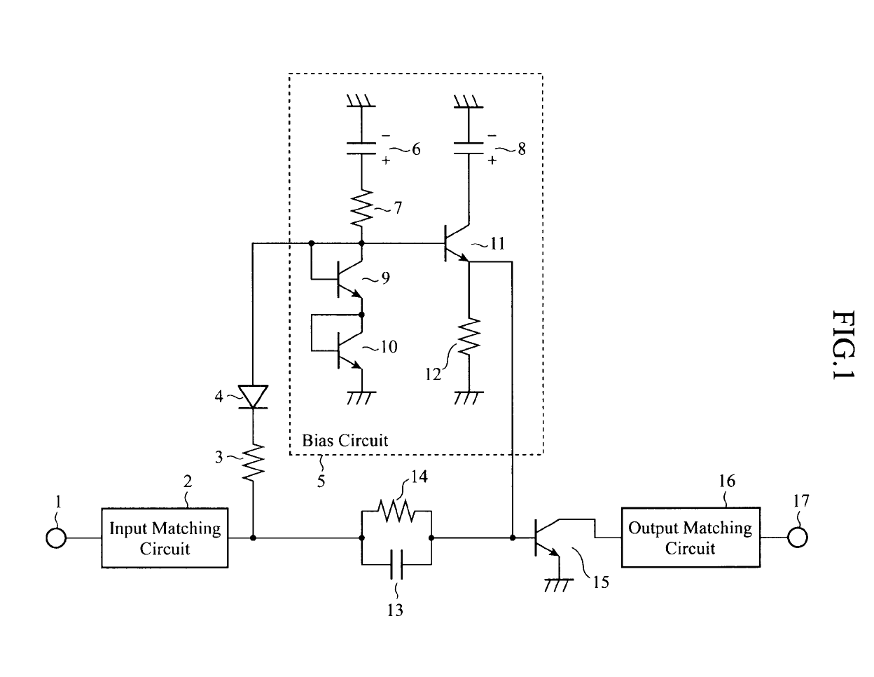

FIG. 1 is a diagram showing a configuration of a high-frequency amplifier of an embodiment 1 in accordance with the present invention. In FIG. 1, an input terminal 1 is a terminal for inputting a modulation wave signal which is a high-frequency signal, and an input matching circuit 2 is a circuit for achieving impedance matching on the input side.

A detection sensitivity control resistance 3 is a resistance having its first end connected to the output side of the input matching circuit 2.

A detecting diode 4 is an element that has its anode connected to a power supply 6 of a bias circuit 5 via a bias resistance 7 and its cathode connected to the detection sensitivity control resistance 3, and that detects an envelope signal of the modulation wave signal input via the input terminal 1. The detecting diode 4 constitutes a detecting unit.

In FIG. 1, although an example using the detecting diode 4 is shown, a PN junction diode with its base terminal and collector terminal short-circuited can be used instead of the detecting diode 4.

The bias circuit 5 is a circuit for supplying the base terminal of an amplifying element 15 with a bias current corresponding to the amplitude of the envelope signal detected by the detecting diode 4. The bias circuit 5 constitutes a bias current supplying unit.

A PN junction diode 9 of the bias circuit 5 has its base terminal and collector terminal short-circuited, and the base terminal and collector terminal are connected to the anode of the detecting diode 4 and to the power supply 6 via a bias resistance 7.

A PN junction diode 10 has its base terminal and collector terminal short-circuited, and the base terminal and collector terminal are connected to the emitter terminal of the PN junction diode 9, and the emitter terminal is connected to a ground.

An NPN bipolar transistor 11 has its base terminal connected to the anode of the detecting diode 4, its collector terminal connected to a power supply 8 for the collector, and its emitter terminal connected to the base terminal of the amplifying element 15.

An emitter grounding resistance 12 has its first end connected to the emitter terminal of the NPN bipolar transistor 11 and its second terminal connected to the ground.

An RF feeder capacitance 13 is a capacitance that has its first end connected to the output side of the input matching circuit 2 and its second terminal connected to the base terminal of the amplifying element 15.

A DC feeder resistance 14 is a resistance connected in parallel with the RF feeder capacitance 13.

The amplifying element 15 is an element that has its gain characteristics controlled in response to the bias current supplied from the bias circuit, and amplifies the modulation wave signal input via the input terminal 1. The amplifying element 15 constitutes an amplifying unit.

An output matching circuit 16 is a circuit for achieving impedance matching at the output side, and an output terminal 17 is a terminal for outputting the modulation wave signal amplified with the amplifying element 15.

Next, the operation will be described. When the modulation wave signal, which is the high-frequency signal, is input via the input terminal 1, the amplifying element 15 amplifies the modulation wave signal and outputs the amplified modulation wave signal.

On this occasion, the detecting diode 4 follows the amplitude of the envelope signal of the modulation wave signal input via the input terminal 1, and detects the amplitude of the envelope signal.

More specifically, it is performed as follows.

The bias of the detecting diode 4 is supplied from the power supply 6 of the bias circuit 5 via the bias resistance 7.

Thus, when the modulation wave signal is input via the input terminal 1, the detection current corresponding to the amplitude of the envelope signal of the modulation wave signal flows through the detecting diode 4.

The detection current flows through the detection sensitivity control resistance 3, DC feeder resistance 14 and amplifying element 15, and its current value increases with an increase of the amplitude of the envelope signal.

When the detecting diode 4 detects the amplitude of the envelope signal, the bias circuit 5 supplies the bias current corresponding to the amplitude of the envelope signal to the base terminal of the amplifying element 15.

When the amplitude of the envelope signal increases and hence the detection current flowing through the detecting diode 4 increases, the NPN bipolar transistor 11 of the bias circuit 5 operates in such a manner as to reduce the bias current supplied to the base terminal of the amplifying element 15.

More specifically, the operation is as follows.

The bias current supplied to the base terminal of the amplifying element 15 is generated by supplying a current from the power supply 6 to the base terminal of the NPN bipolar transistor 11. When the modulation wave signal is input via the input terminal 1 and hence the detection current corresponding to the amplitude of the envelope signal of the modulation wave signal flows through the detection diode 4, the current supplied from the power supply 6 to the base terminal of the NPN bipolar transistor 11 reduces by the amount of the detection current, thereby decreasing the bias current supplied to the base terminal of the amplifying element 15.

Thus, the bias current is controlled in accordance with the amplitude of the envelope signal of the input modulation wave signal, and the current supplied from the bias circuit 5 to the amplifying element 15 is suppressed with an increase of the amplitude of the envelope signal. As a result, the gain of the amplifying element 15 reduces.

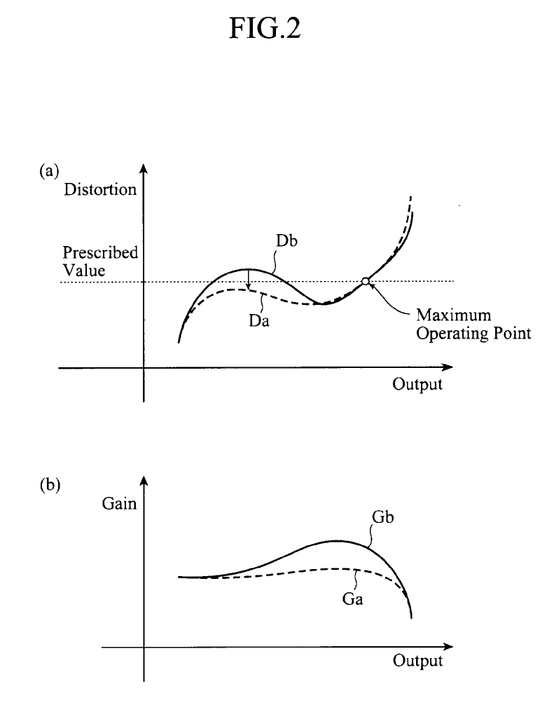

FIG. 2 is a diagram showing distortion characteristics and gain characteristics of the high-frequency amplifier of the embodiment 1 in accordance with the present invention.

In FIG. 2, solid lines show distortion characteristics Db and gain characteristics Gb before using the present invention, and broken lines show distortion characteristics Da and gain characteristics Ga when the present invention is used.

As is clear from FIG. 2, the gain characteristics Gb before using the present invention have characteristics bending upward, and the distortion characteristics Db do not satisfy prescribed distortion in a low output area.

In contrast with this, the gain characteristics Ga when using the present invention can suppress the characteristics bending upward.

In addition, the distortion characteristics Da can satisfy the prescribed distortion even in a low output area.

Incidentally, using the present invention does not reduce the maximum operation point.

As is clear from the above, according to the present embodiment 1, it is configured in such a manner that the detecting diode 4 and the NPN bipolar transistor 11 of the bias circuit 5 are biased by the common power supply 6, and that when the amplitude of the envelope signal increases, the bias current supplied from the NPN bipolar transistor 11 to the amplifying element 15 is suppressed in response to the amplitude of the envelope signal. Accordingly, it offers an advantage of being able to obviate the need for the power supply and the DC blocking capacitance of the detector circuit, to follow the modulation speed of the modulation wave, and to prevent the deterioration of the distortion characteristics involved in the gain reduction near the saturation even if the modulation wave signal with the high crest factor is input.

Although the present embodiment 1 is shown by way of example that connects the RF feeder capacitance 13 between the input matching circuit 2 and the amplifying element 15, and connects the DC feeder resistance 14 in parallel with RF feeder capacitance 13, a configuration is also possible which connects only the

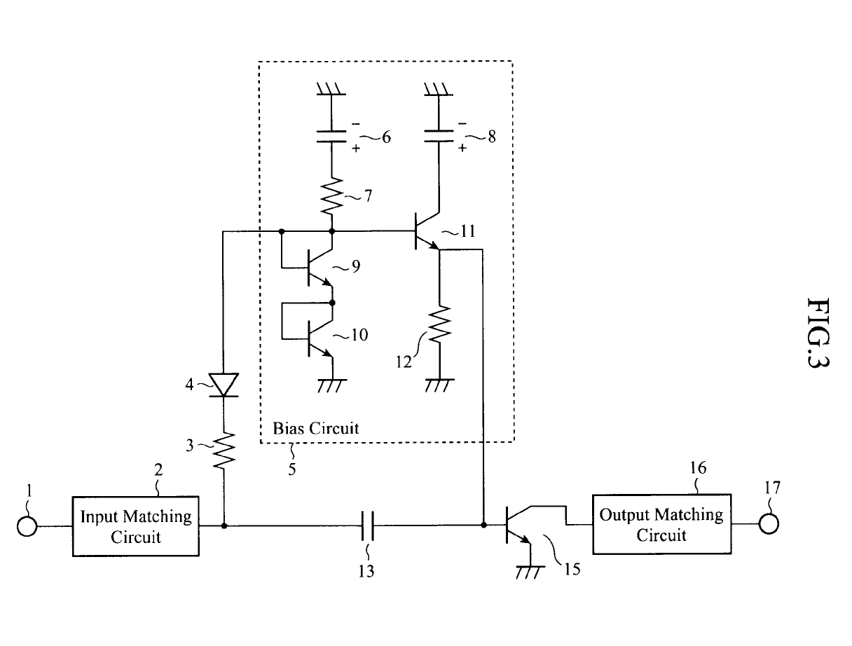

RF feeder capacitance 13 between the input matching circuit 2 and the amplifying element 15 and removes the DC feeder resistance 14 as shown in FIG. 3.

In this case, since the offset current of the detecting diode 4 does not flow, the input power level for operation increases as compared with the case where the DC feeder resistance 14 is connected.

As described above, removing the DC feeder resistance 14 can reduce the number of components.

### EMBODIMENT 2

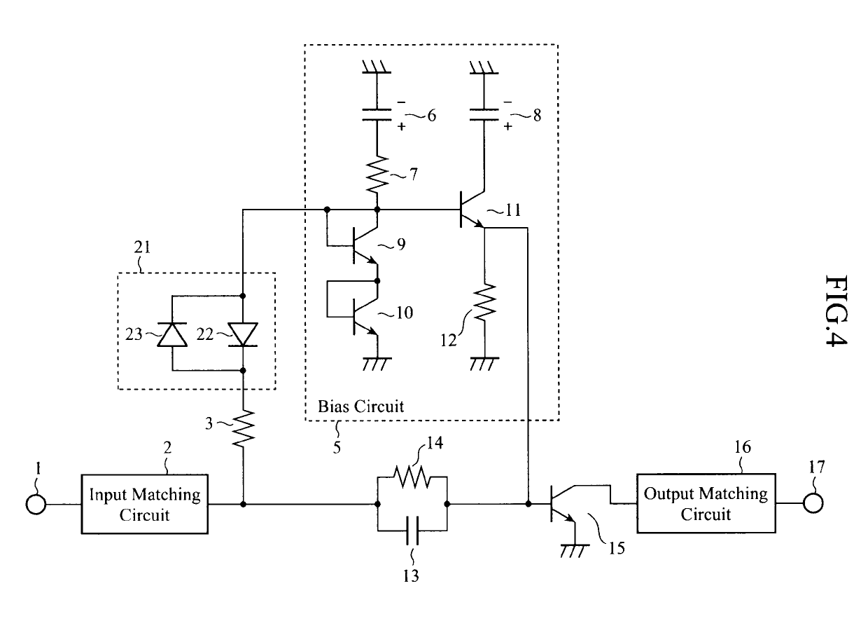

FIG. 4 is a diagram showing a configuration of a high-frequency amplifier of an embodiment 2 in accordance with the present invention. In FIG. 4, since the same reference numerals as those of FIG. 1 designate the same or like portions, their description will be omitted here.

A detecting antiparallel diode pair 21 is an element that detects the envelope signal of the modulation wave signal input via the input terminal 1. Incidentally, the detecting antiparallel diode pair 21 constitutes a detecting unit.

A detecting antiparallel diode 22 has its anode connected to the power supply 6 of the bias circuit 5 via the bias resistance 7, and its cathode connected to the detection sensitivity control resistance 3.

A detecting antiparallel diode 23 differs from the detecting antiparallel diode 22 in its direction with its cathode connected to the power supply 6 of the bias circuit 5 via the bias resistance 7 and its anode connected to the detection sensitivity control resistance 3.

Although FIG. 4 shows an example that uses the detecting antiparallel diodes 22 and 23, PN junction diodes with their base terminal and collector terminal short-circuited can also be used in place of the detecting antiparallel diodes 22 and 23.

Next, the operation will be described.

When the modulation wave signal is input via the input terminal 1, the amplifying element 15 amplifies the modulation wave signal and outputs the amplified modulation wave signal in the same manner as the foregoing embodiment 1.

On this occasion, the detecting antiparallel diode pair 21 follows the amplitude of the envelope signal of the modulation wave signal input via the input terminal 1, and detects the amplitude of the envelope signal.

More specifically, the operation is as follows.

The bias of the detecting antiparallel diode pair 21 is supplied from the power supply 6 of the bias circuit 5 via the bias resistance 7.

Thus, when the modulation wave signal is input via the input terminal 1, the detection current corresponding to the amplitude of the envelope signal of the modulation wave signal flows through the detecting antiparallel diode 22 of the detecting antiparallel diode pair 21.

The detection current flows through the detection sensitivity control resistance 3, DC feeder resistance 14 and amplifying element 15, and its current value increases with an increase of the amplitude of the envelope signal.

However, when the amplitude of the envelope signal further increases, since the detection current comes to flow through the detecting antiparallel diode 23 (the detection current in the direction opposite to the detection current flowing through the detecting antiparallel diode 22), the detection current flowing from the detecting antiparallel diode pair 21 to the detection sensitivity control resistance 3 reduces.

When the detecting antiparallel diode pair 21 detects the amplitude of the envelope signal, the bias circuit 5 supplies the bias current corresponding to the amplitude of the envelope signal to the base terminal of the amplifying element 15.

More specifically, when the amplitude of the envelope signal increases and hence the detection current flowing through the detecting antiparallel diode pair 21 increases, the NPN bipolar transistor 11 of the bias circuit 5 operates in such a manner as to reduce the bias current supplied to the base terminal of the amplifying element 15. In addition, when the amplitude of the envelope signal further increases, and hence the detection current also flows through the detecting antiparallel diode 23, it operates in such a manner as to increase the bias current supplied to the base terminal of the amplifying element 15.

More specifically, the operation is as follows.

The bias current supplied to the base terminal of the amplifying element 15 is generated by supplying a current from the power supply 6 to the base terminal of the NPN bipolar transistor 11. When the modulation wave signal is input via the input terminal 1 and hence the detection current corresponding to the amplitude of the envelope signal of the modulation wave signal flows through the detecting antiparallel diode 22 of the detecting antiparallel diode pair 21 (at this stage, the current does not flow through the detecting antiparallel diode 23), the current supplied from the power supply 6 to the base terminal of the NPN bipolar transistor 11 reduces by the amount of the detection current, thereby decreasing the bias current supplied to the base terminal of the amplifying element 15.

When the amplitude of the envelope signal input via the input terminal 1 further increases, the detection current comes to flow through the detecting antiparallel diode 23 of the detecting antiparallel diode pair 21. Thus, the detection current flowing from the detecting antiparallel diode pair 21 to the detection sensitivity control resistance 3 decreases by the amount of the detection current and hence increases the current supplied from the power supply 6 to the base terminal of the NPN bipolar transistor 11, thereby increasing the bias current supplied to the base terminal of the amplifying element 15.

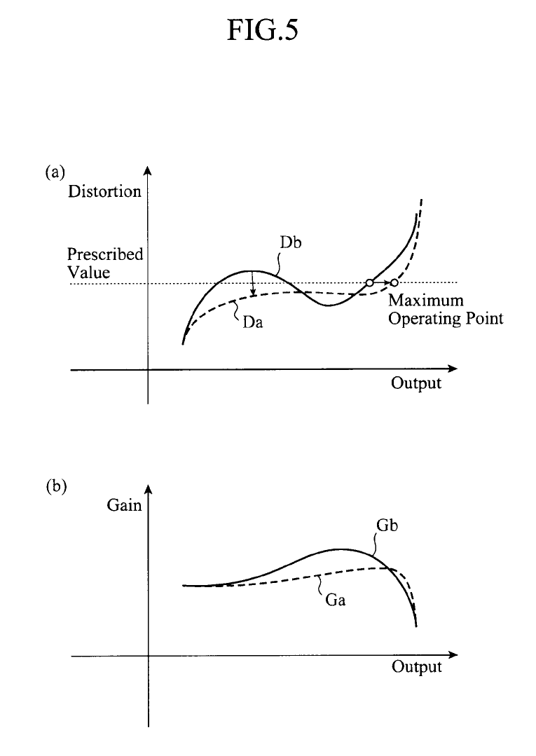

FIG. 5 is a diagram showing distortion characteristics and gain characteristics of the high-frequency amplifier of the embodiment 2 in accordance with the present invention.

In FIG. 5, solid lines show distortion characteristics Db and gain characteristics Gb before using the present invention, and broken lines show distortion characteristics Da and gain characteristics Ga when the present invention is used.

As is clear from FIG. 5, the gain characteristics Gb before using the present invention have characteristics bending upward, and the distortion characteristics Db do not satisfy prescribed distortion in a low output area.

In contrast with this, the gain characteristics Ga when using the present invention can suppress the characteristics bending upward.

In addition, the distortion characteristics Da can satisfy the prescribed distortion even in the low output area.

Incidentally, using the present invention can increase the maximum operation point.

As is clear from the above, according to the present embodiment 2, it is configured in such a manner that the detecting antiparallel diode pair 21 having two detecting antiparallel diodes 22 and 23 connected in parallel in the directions opposite to each other constitutes a detecting unit, that when the amplitude of the envelope signal increases, the bias current supplied from the bias circuit 5 to the base of the amplifying element 15 is suppressed, and that when the amplitude of the envelope signal further increases and the detection current comes to flow through the detecting antiparallel diode 23, the bias current supplied from the bias circuit 5 to the base terminal of the amplifying element 15 increases. Accordingly, it offers an advantage of being able to obviate the need for the power supply and the DC blocking capacitance of the detector circuit, to follow the modulation speed of the modulation wave, and to prevent the deterioration of the distortion characteristics involved in the gain reduction near the saturation even if the modulation wave signal with the high crest factor is input. In addition, it offers an advantage of being able to increase the maximum operation point.

### EMBODIMENT 3

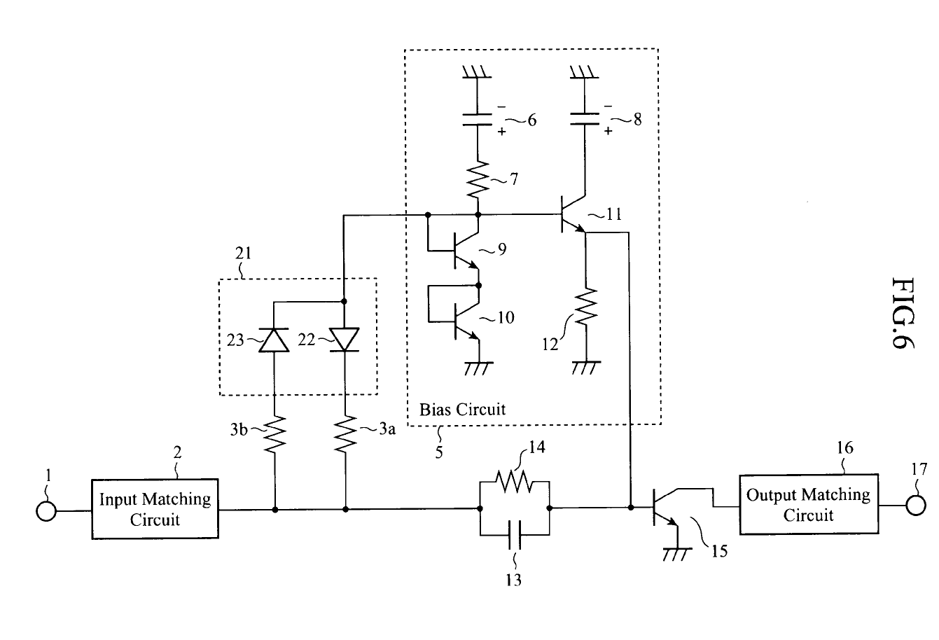

FIG. 6 is a diagram showing a configuration of a high-frequency amplifier of an embodiment 3 in accordance with the present invention. In FIG. 3, since the same reference numerals as those of FIG. 4 designate the same or like portions, their description will be omitted here.

A detection sensitivity control resistance 3a is a resistance having its first end connected to the output side of the input matching circuit 2 and its second terminal connected to the cathode (input terminal) of the detecting antiparallel diode 22 constituting the detecting antiparallel diode pair 21.

A detection sensitivity control resistance 3b is a resistance having its first end connected to the output side of the input matching circuit 2 and its second terminal connected to the anode (input terminal) of the detecting antiparallel diode 23 constituting the detecting antiparallel diode pair 21.

Although the foregoing embodiment 2 shows an example that connects the detecting antiparallel diodes 22 and 23 constituting the detecting antiparallel diode pair 21 to the output side of the input matching circuit 2 via the common detection sensitivity control resistance 3, the detecting antiparallel diodes 22 and 23 can be connected to the output side of the input matching circuit 2 via the separate detection sensitivity control resistances 3a and 3b.

Although FIG. 6 shows a case that uses the detecting antiparallel diodes 22 and 23, PN junction diodes with their base terminal and collector terminal short-circuited can also be used instead of the detecting antiparallel diodes 22 and 23.

Next, the operation will be described.

When the modulation wave signal is input via the input terminal 1, the amplifying element 15 amplifies the modulation wave signal and outputs the amplified modulation wave signal in the same manner as in the foregoing embodiment 1.

On this occasion, the modulation wave signal input via the input terminal 1 is supplied to the detecting antiparallel diodes 22 and 23 via the detection sensitivity control resistances 3a and 3b, respectively.

Thus, the detecting antiparallel diode pair 21 follows the amplitude of the envelope signal of the modulation wave signal input via the input terminal 1 and detects the amplitude of the envelope signal.

However, the present embodiment 3 differs from the foregoing embodiment 2 in that the detecting antiparallel diodes 22 and 23 are connected separately with the detection sensitivity control resistances 3a and 3b, and that the detection sensitivity control resistance 3a and detection sensitivity control resistance 3b have different resistance values.

For example, consider a case where the resistance value of the detection sensitivity control resistance 3b is greater than the resistance value of the detection sensitivity control resistance 3a (detection sensitivity control resistance 3b>detection sensitivity control resistance 3a=detection sensitivity control resistance 3). In this case, unless the input signal to the detecting antiparallel diode 23 exceeds that of the foregoing embodiment 2, the detecting antiparallel diode 23 does not operate.

Accordingly, the input level at which the detecting antiparallel diode 23 operates increases, and hence the input level of the modulation wave signal increases at which the bias current supplied to the amplifying element 15 changes from reduction to increase.

On the other hand, consider a case where the resistance value of the detection sensitivity control resistance 3b is smaller than the resistance value of the detection sensitivity control resistance 3a (detection sensitivity control resistance 3b<detection sensitivity control resistance 3a=detection sensitivity control resistance 3). In this case, even if the input signal to the detecting antiparallel diode 23 is smaller than that of the foregoing embodiment 2, the detecting antiparallel diode 23 can operate.

Accordingly, the input level at which the detecting antiparallel diode 23 operates reduces, and hence the input level of the modulation wave signal reduces at which the bias current supplied to the amplifying element 15 changes from reduction to increase.

Thus, varying the resistance values of the detection sensitivity control resistances 3a and 3b appropriately makes it possible to adjust the gain characteristics of the amplifying element 15.

### EMBODIMENT 4

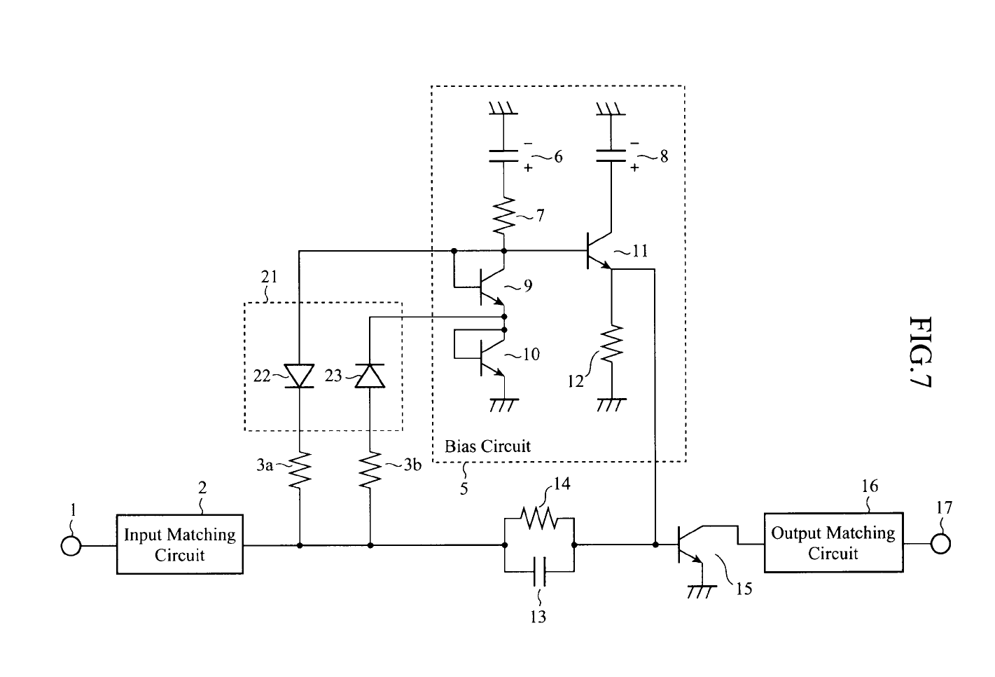

FIG. 7 is a diagram showing a configuration of a high-frequency amplifier of an embodiment 4 in accordance with the present invention. In FIG. 7, since the same reference numerals as those of FIG. 6 designate the same or like portions, their description will be omitted here.

Although the foregoing embodiment 3 shows a case where the anode of the detecting antiparallel diode 22 and the cathode of the detecting antiparallel diode 23 are connected to the same point, they can be connected to different points.

More specifically, in the present embodiment 4, although the detecting antiparallel diode 22 has its anode connected to the bias resistance 7 or the base terminal of the PN junction diode 9 as in the foregoing embodiment 3, the detecting antiparallel diode 23 has its cathode connected to the emitter terminal of the PN junction diode 9 and the collector terminal of the PN junction diode 10.

In this case, the detecting antiparallel diode 23 is biased in the opposite direction via the PN junction diode.

In the foregoing embodiment 3, the same voltage is applied to the detecting antiparallel diode 22 and the detecting antiparallel diode 23 in the opposite direction. In the present embodiment 4, however, since the bias is applied to the detecting antiparallel diode 23 in the opposite direction via the PN junction diode 9, the detecting antiparallel diode 23 operates at a smaller input level of the modulation wave signal than in the foregoing embodiment 3.

Accordingly, the input level at which the detecting antiparallel diode 23 operates reduces, and hence the input level of the modulation wave signal reduces at which the bias current supplied to the amplifying element 15 changes from reduction to increase.

### EMBODIMENT 5

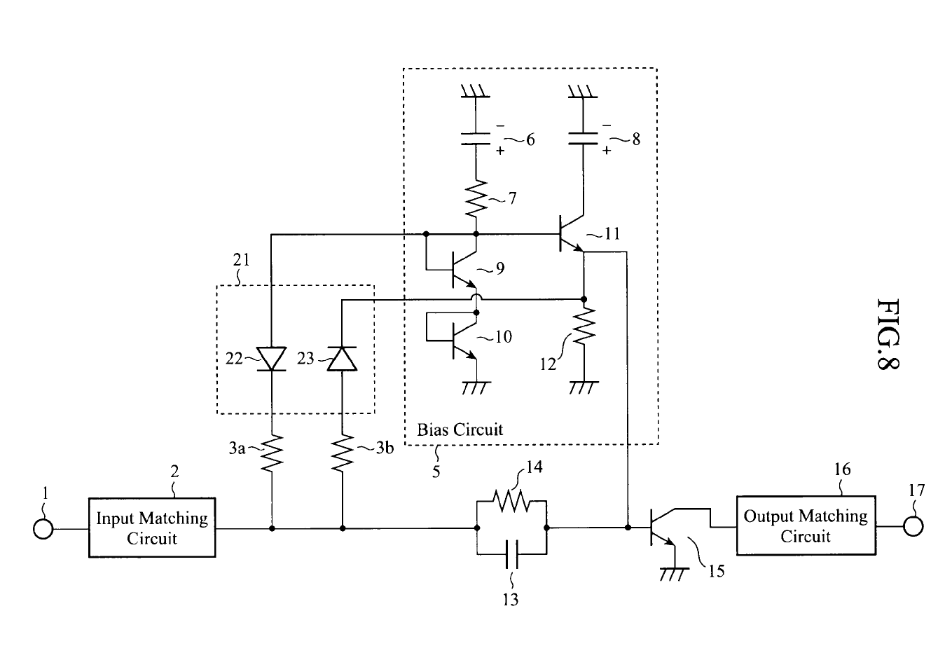

FIG. 8 is a diagram showing a configuration of a high-frequency amplifier of an embodiment 5 in accordance with the present invention. In FIG. 8, since the same reference numerals as those of FIG. 7 designate the same or like portions, their description will be omitted here.

Although the foregoing embodiment 4 shows a case where the detecting antiparallel diode 23 has its cathode connected to the emitter terminal of the PN junction diode 9 and the collector terminal of the PN junction diode 10, the detecting antiparallel diode 23 can have its cathode connected to the emitter terminal of the NPN bipolar transistor 11 and the emitter grounding resistance 12.

In the present embodiment 5, the detecting antiparallel diode 23 is biased in the opposite direction via the NPN bipolar transistor 11.

In the present embodiment 5 also, since the input level at which the detecting antiparallel diode 23 operates reduces as in the foregoing embodiment 4, the input level of the modulation wave signal reduces at which the bias current supplied to the amplifying element 15 changes from reduction to increase.

### EMBODIMENT 6

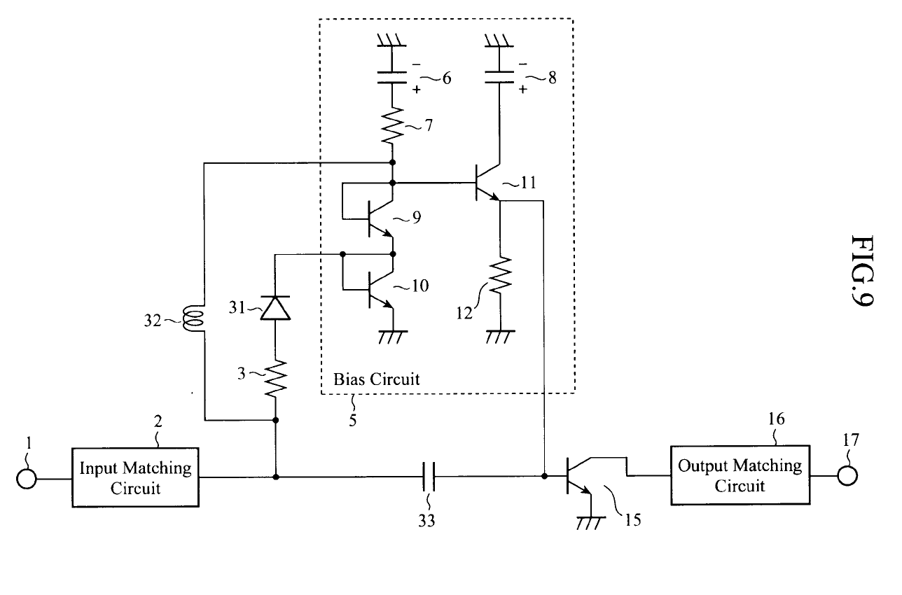

FIG. 9 is a diagram showing a configuration of a high-frequency amplifier of an embodiment 6 in accordance with the present invention. In FIG. 9, since the same reference numerals as those of FIG. 1 designate the same or like portions, their description will be omitted here.

A detecting diode 31 is an element that has its cathode connected to the power supply 6 of the bias circuit 5 via the PN junction diode 9 and bias resistance 7 and its anode connected to the detection sensitivity control resistance 3, and that detects the envelope signal of the modulation wave signal input via the input terminal 1. Incidentally, the detecting diode 31 constitutes a detecting unit.

Although FIG. 9 shows an example using the detecting diode 31, a PN junction diode with its base terminal and collector terminal short-circuited can be used instead of the detecting diode 31.

A DC feeder inductor 32 is an inductor that has its first end connected to the output side of the input matching circuit 2 and its second terminal connected to the bias resistance 7.

An RF feeder capacitance-DC blocking capacitance 33 is a capacitance that has its first end connected to the output side of the input matching circuit 2 and its second terminal connected to the base terminal of the amplifying element 15.

Next, the operation will be described.

When the modulation wave signal is input via the input terminal 1, the amplifying element 15 amplifies the modulation wave signal and outputs the amplified modulation wave signal in the same manner as in the foregoing embodiment 1.

On this occasion, the detecting diode 31 follows the amplitude of the envelope signal of the modulation wave signal input via the input terminal 1 and detects the amplitude of the envelope signal.

More specifically, the operation is as follows.

The bias of the detecting diode 31 is supplied from the power supply 6 of the bias circuit 5 via the PN junction diode 9 and bias resistance 7.

Accordingly, when the modulation wave signal is input via the input terminal 1, the detection current corresponding to the amplitude of the envelope signal of the modulation wave signal flows through the detecting diode 31.

The detection current flows through the DC feeder inductor 32, and its current value increases with the amplitude of the envelope signal.

When the detecting diode 31 detects the amplitude of the envelope signal, the bias circuit 5 supplies the bias current corresponding to the amplitude of the envelope signal to the base terminal of the amplifying element 15.

In other words, when the amplitude of the envelope signal increases and the detection current flowing through the detecting diode 31 increases, the NPN bipolar transistor 11 of the bias circuit 5 operates in such a manner as to increase the bias current supplied to the base terminal of the amplifying element 15.

More specifically, the operation is as follows.

The bias current supplied to the base terminal of the amplifying element 15 is generated by supplying a current from the power supply 6 to the base terminal of the NPN bipolar transistor 11. When the modulation wave signal is input via the input terminal 1 and hence the detection current corresponding to the amplitude of the envelope signal of the modulation wave signal flows through the detection diode 31, the current supplied from the power supply 6 to the base terminal of the NPN bipolar transistor 11 increases by the amount of the detection current, thereby increasing the bias current supplied to the base terminal of the amplifying element 15.

Thus, the bias current is controlled in accordance with the amplitude of the envelope signal of the input modulation wave signal, and the current supplied from the bias circuit 5 to the amplifying element 15 is increased with an increase of the amplitude of the envelope signal. As a result, the gain of the amplifying element 15 increases.

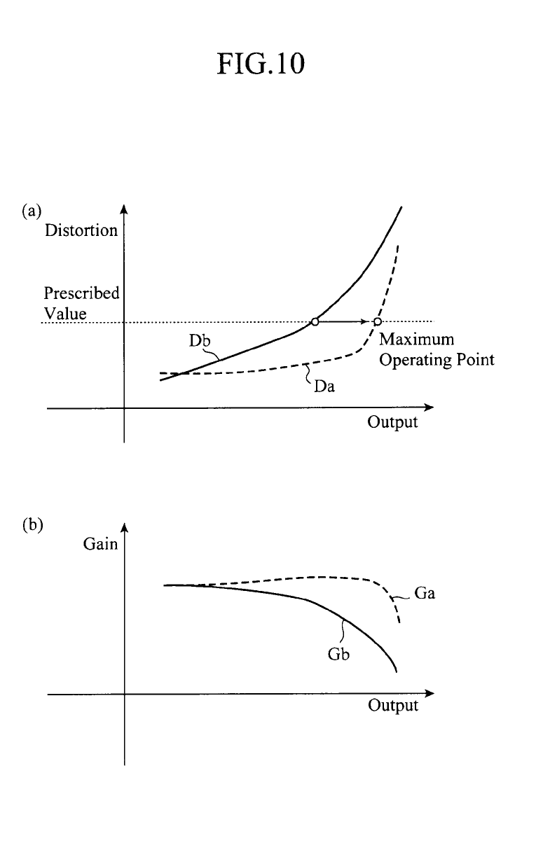

FIG. 10 is a diagram showing distortion characteristics and gain characteristics of the high-frequency amplifier of the embodiment 6 in accordance with the present invention.

In FIG. 10, solid lines show distortion characteristics Db and gain characteristics Gb before using the present invention, and broken lines show distortion characteristics Da and gain characteristics Ga when the present invention is used.

As is clear from FIG. 10, the gain characteristics Gb before using the present invention have declining characteristics, and the distortion characteristics Db do not satisfy prescribed distortion in a high output area.

In contrast with this, the gain characteristics Ga when using the present invention can suppress the declining characteristics.

In addition, the distortion characteristics Da can satisfy the prescribed distortion even in a high output area.

Incidentally, using the present invention increases the maximum operation point.

As is clear from the above, according to the present embodiment 6, it is configured in such a manner that the detecting diode 31 and the NPN bipolar transistor 11 of the bias circuit 5 are biased by the common power supply 6, and that when the amplitude of the envelope signal increases, the bias current supplied from the NPN bipolar transistor 11 to the amplifying element 15 increases in response to the amplitude of the envelope signal. Accordingly, it offers an advantage of being able to obviate the need for the power supply and the DC blocking capacitance of the detector circuit, to follow the modulation speed of the modulation wave, and to prevent the deterioration of the distortion characteristics involved in the gain increase near the saturation even if the modulation wave signal with the high crest factor is input. In addition, it offers an advantage of being able to increase the maximum operation point.

### EMBODIMENT 7

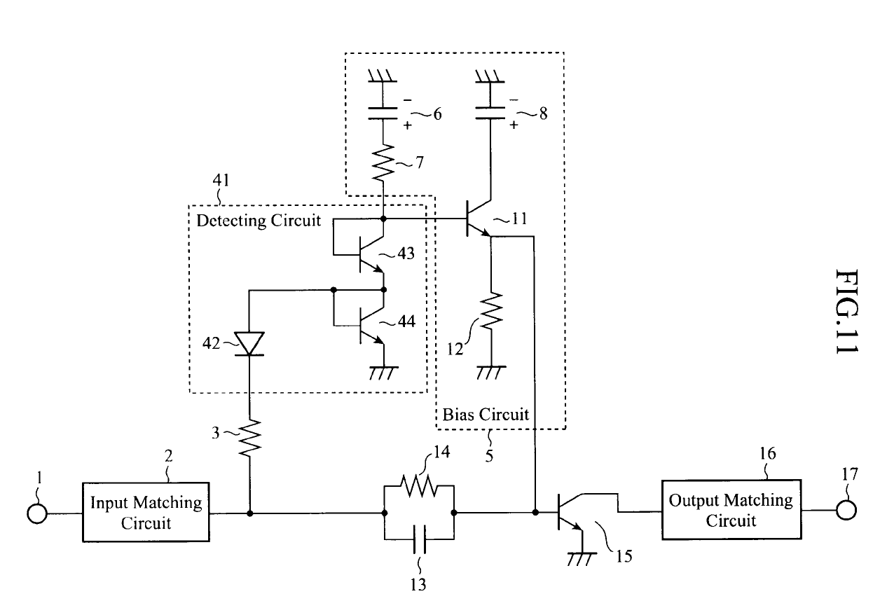

FIG. 11 is a diagram showing a configuration of a high-frequency amplifier of an embodiment 7 in accordance with the present invention. In FIG. 11, since the same reference numerals as those of FIG. 1 designate the same or like portions, their description will be omitted here.

A detector circuit 41 is a three-stage construction detecting unit including one detecting diode 42 and two PN junction diodes 43 and 44, and detects the envelope signal of the modulation wave signal input via the input terminal 1.

The detecting diode 42 is an element that has its anode connected to the power supply 6 of the bias circuit 5 via the PN junction diode 43 and bias resistance 7 and its cathode connected to the detection sensitivity control resistance 3, and that detects the envelope signal of the modulation wave signal input via the input terminal 1.

Although FIG. 11 shows an example using the detecting diode 42, a PN junction diode with its base terminal and collector terminal short-circuited can also be used instead of the detecting diode 42.

The PN junction diode 43 has its base terminal and collector terminal short-circuited, and the base terminal and collector terminal are connected to the power supply 6 via the bias resistance 7.

The PN junction diode 44 has its base terminal and collector terminal short-circuited with the base terminal and collector terminal being connected to the emitter terminal of the EN j unction diode 43, and has its emitter terminal connected to the ground.

Next, the operation will be described.

When the modulation wave signal is input via the input terminal 1, the amplifying element 15 amplifies the modulation wave signal and outputs the amplified modulation wave signal in the same manner as in the foregoing embodiment 1

On this occasion, the three-stage detector circuit 41 follows the amplitude of the envelope signal of the modulation wave signal input via the input terminal 1, and detects the amplitude of the envelope signal.

More specifically, the operation is as follows.

The bias of the three-stage detector circuit 41 is supplied from the power supply 6 of the bias circuit 5 via the PN junction diode 43 and bias resistance 7.

Accordingly, when the modulation wave signal is input via the input terminal 1, the detection current corresponding to the amplitude of the envelope signal of the modulation wave signal flows through the detecting diode 42 of the detector circuit 41.

The detection current flows through the detection sensitivity control resistance 3, DC feeder resistance 14 and amplifying element 15, and its current value increases with the amplitude of the envelope signal.

When the detector circuit 41 detects the amplitude of the envelope signal, the bias circuit 5 supplies the bias current corresponding to the amplitude of the envelope signal to the base terminal of the amplifying element 15.

In other words, when the amplitude of the envelope signal increases and the detection current flowing through the detecting diode 42 of the detector circuit 41 increases, the NPN bipolar transistor 11 of the bias circuit 5 operates in such a manner as to reduce the bias current supplied to the base terminal of the amplifying element 15.

More specifically, the operation is as follows.

The bias current supplied to the base terminal of the amplifying element 15 is generated by supplying a current from the power supply 6 to the base terminal of the NPN bipolar transistor 11. When the modulation wave signal is input via the input terminal 1 and hence the detection current corresponding to the amplitude of the envelope signal of the modulation wave signal flows through the detection diode 42, the current supplied from the power supply 6 to the base terminal of the NPN bipolar transistor 11 reduces by the amount of the detection current, thereby decreasing the bias current supplied to the base terminal of the amplifying element 15.

Thus, the bias current is controlled in accordance with the amplitude of the envelope signal of the input modulation wave signal, and the current supplied from the bias circuit 5 to the amplifying element 15 is suppressed with an increase of the amplitude of the envelope signal. As a result, the gain of the amplifying element 15 reduces.

As is clear from the above, according to the present embodiment 7, it is configured in such a manner as to detect the amplitude of the envelope signal using the three-stage construction detector circuit 41 including the one detecting diode 42 two PN junction diodes 43 and 44. Accordingly, it offers an advantage of being able to make the detection sensitivity higher than the foregoing embodiment 1, and to control the bias current supplied to the amplifying element 15 at higher accuracy.

Incidentally, although the present embodiment 7 shows an example using the three-stage detector circuit 41 instead of the detecting diode 4 in the foregoing embodiment 1, a configuration is also possible which employs, instead of the detecting antiparallel diode pair 21 in the foregoing embodiment 2, a three-stage construction detector circuit including one detecting antiparallel diode pair 21 and two PN junction diodes 43 and 44, and detects the amplitude of the envelope signal.

Alternatively, instead of the detecting diode 31 in the foregoing embodiment 6, it is also possible to employ a three-stage construction detector circuit including one detecting diode 31 and two PN junction diodes 43 and 44 to detect the amplitude of the envelope signal.

### EMBODIMENT 8

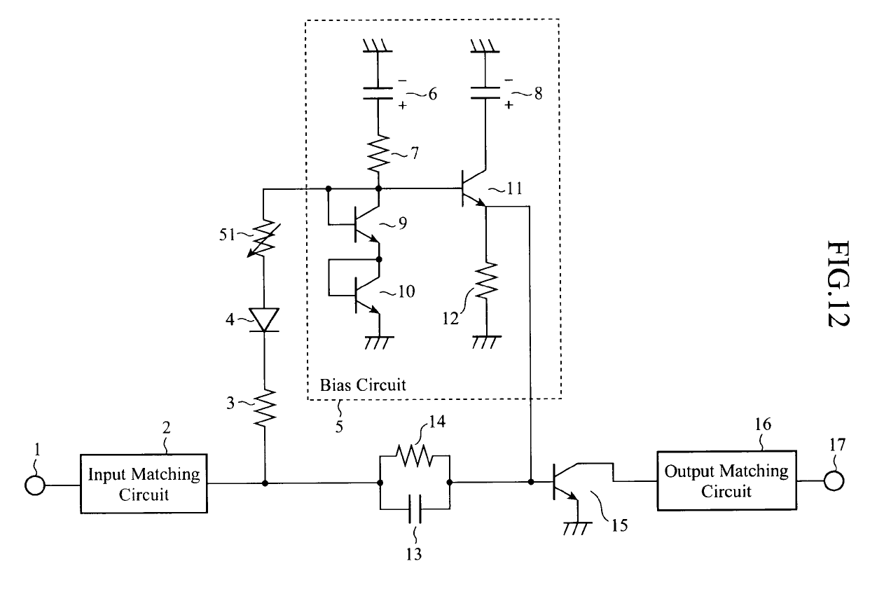

FIG. 12 is a diagram showing a configuration of a high-frequency amplifier of an embodiment 8 in accordance with the present invention. In FIG. 12, since the same reference numerals as those of FIG. 1 designate the same or like portions, their description will be omitted here.

A variable resistance 51 is a resistance connected in series with the detecting diode 4 for adjusting the voltage applied to the detecting diode 4.

Although FIG. 12 shows an example in which the variable resistance 51 is connected in series with the detecting diode 4, the variable resistance 51 can be connected in parallel with the detecting diode 4.

Next, the operation will be described.

The detecting diode 4 follows the amplitude of the envelope signal of the modulation wave signal input via the input terminal 1 and detects the amplitude of the envelope signal in the same manner as the foregoing embodiment 1.

In the present embodiment 8, since the variable resistance 51 is connected in series with the detecting diode 4, the bias conditions of the detecting diode 4 can be adjusted by varying the voltage applied to the detecting diode 4 by controlling the resistance value of the variable resistance 51.

Because the detection current flowing through the detecting diode 4 can be adjusted by varying the bias conditions of the detecting diode 4, the bias current supplied to the amplifying element 15 can be controlled.

Although the present embodiment 8 shows an example in which the variable resistance 51 is connected in series or in parallel with the detecting diode 4 in the foregoing embodiment 1, the variable resistance 51 can be connected in series or in parallel with the detecting antiparallel diode pair 21 in the foregoing embodiment 2.

In addition, the variable resistance 51 can be connected in series or in parallel with the detecting diode 31 in the foregoing embodiment 6 or with the detector circuit 41 in the foregoing embodiment 7.

### EMBODIMENT 9

FIG. 13 is a diagram showing a configuration of a high-frequency amplifier of an embodiment 9 in accordance with the present invention. In FIG. 13, since the same reference numerals as those of FIG. 1 designate the same or like portions, their description will be omitted here.

A capacitor 52 is connected in parallel with the detecting diode 4 to increase the sensitivity of the detecting diode 4.

Next, the operation will be described.

The detecting diode 4 follows the amplitude of the envelope signal of the modulation wave signal input via the input terminal 1 and detects the amplitude of the envelope signal in the same manner as the foregoing embodiment 1.

In the present embodiment 9, since the capacitor 52 is connected in parallel with the detecting diode 4, the capacitor 52 fixes the impedance of the detecting diode 4, thereby being able to increase the sensitivity of the detecting diode 4.

Although the present embodiment 9 shows an example in which the capacitor 52 is connected in parallel with the detecting diode 4 in the foregoing embodiment 1, the capacitor 52 can be connected in parallel with the detecting antiparallel diode pair 21 in the foregoing embodiment 2.

In addition, the capacitor 52 can be connected in parallel with the detecting diode 31 in the foregoing embodiment 6 or with the detector circuit 41 in the foregoing embodiment 7.

### EMBODIMENT 10

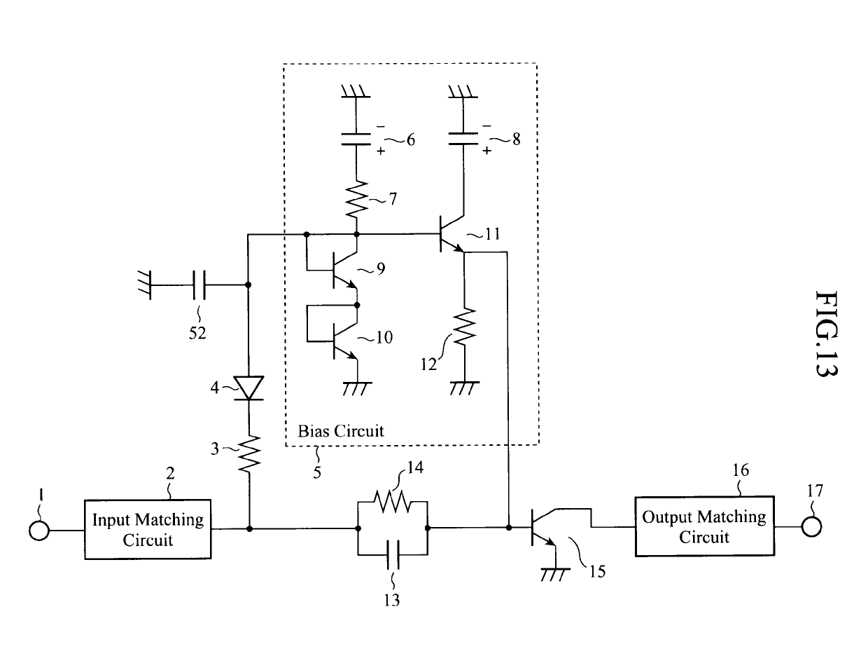

FIG. 14 is a diagram showing a configuration of a high-frequency amplifier of an embodiment 10 in accordance with the present invention. In FIG. 14, since the same reference numerals as those of FIG. 1 designate the same or like portions, their description will be omitted here.

A resistance 53 has its first end connected to the emitter terminal of the PN junction diode 9 (diode) and its second terminal connected to the ground. The resistance 53 has a resistance value equivalent to the emitter grounding resistance 12 (second resistance) with its first end connected to the emitter terminal of the NPN bipolar transistor 11 (transistor).

The present embodiment 10 is configured in such a manner that the resistance 53 replaces the PN junction diode 10 in the foregoing embodiment 1, and the resistance 53 has the resistance value equivalent to the emitter grounding resistance 12.

Thus using the resistance 53 instead of the PN junction diode 10 can prevent the current supplied to the NPN bipolar transistor 11 from being reduced too much near the saturation of the amplifying element 15.

More specifically, the operation is as follows.

In the foregoing embodiment 1, when a large modulation wave signal is supplied to the detecting diode 4, a current flows through the PN junction diodes 9 and 10, as well.

In this case, since the current flowing through the PN junction diode 10 varies exponentially, the current supplied to the NPN bipolar transistor 11 decreases sharply near the saturation of the amplifying element 15, thereby reducing the gain of the amplifying element 15 greatly.

In contrast with this, in the present embodiment 10, since the current flowing through the resistance 53 instead of the PN junction diode 10 increases linearly, it can achieve stable gain reduction.

Although the present embodiment 10 shows an example that replaces the PN junction diode 10 in the foregoing embodiment 1 with the resistance 53, it is also possible to replace the PN junction diode 10 in the foregoing embodiments 2 and 6 with the resistance 53, which can moderate the gain characteristics near the saturation of the amplifying element 15.

### EMBODIMENT 11

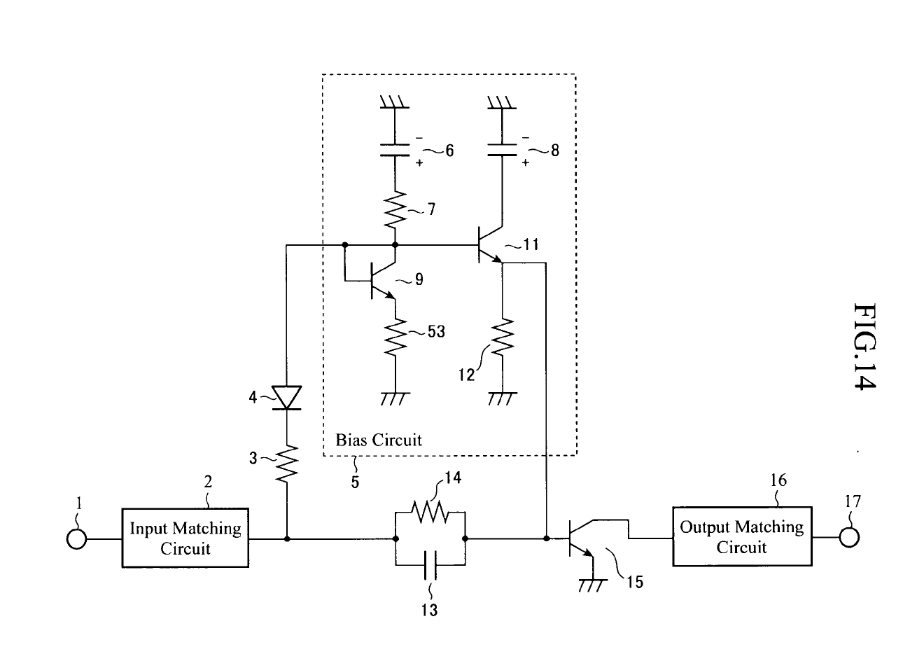

FIG. 15 is a diagram showing a configuration of a high-frequency amplifier of an embodiment 11 in accordance with the present invention. In FIG. 15, since the same reference numerals as those of FIG. 1 designate the same or like portions, their description will be omitted here.

An NPN bipolar transistor 11a has its base terminal connected to the anode of the detecting diode 4, its collector terminal connected to a collector power supply 8a, and its emitter terminal connected to the base terminal of the amplifying element 15.

An emitter grounding resistance 12a has its first end connected to the emitter terminal of the NPN bipolar transistor 11a and its second terminal connected to the ground.

An NPN bipolar transistor 11b has its base terminal connected to the anode of the detecting diode 4 and the base terminal of the NPN bipolar transistor 11a and so on, and its collector terminal connected to a collector power supply 8b.

An emitter grounding resistance 12b has its first end connected to the emitter terminal of the NPN bipolar transistor 11b and its second terminal connected to the ground.

The present embodiment 11 will be described by way of example in which the emitter follower circuit constituting the bias circuit 5 has a two-stage construction.

Next, the operation will be described.

The detecting diode 4 follows the amplitude of the envelope signal of the modulation wave signal input via the input terminal 1 and detects the amplitude of the envelope signal in the same manner as in the foregoing embodiment 1.

In this case, when the amplitude of the envelope signal increases, currents supplied to the NPN bipolar transistor 11a and NPN bipolar transistor 11b reduce, thereby reducing the gain of the amplifying element 15.

In the foregoing embodiment 1, the bias circuit 5 includes the PN junction diodes 9 and 10, and the PN junction diodes 9 and 10 are biased at approximately constant value by the power supply 6.

In the present embodiment 11, the bias circuit 5 includes the NPN bipolar transistor 11b and emitter grounding resistance 12b instead of the PN junction diodes 9 and 10 in the foregoing embodiment 1. Biasing the collector terminal of the NPN bipolar transistor 11b separately makes it possible to vary the current flowing through the NPN bipolar transistor 11a by increasing or decreasing the current flowing through the NPN bipolar transistor 11b and emitter grounding resistance 12b. As a result, the gain of the amplifying element 15 can be adjusted.

Although the present embodiment 11 shows the bias circuit 5 that makes the emitter follower circuit a two-stage construction in the foregoing embodiment 1, the bias circuit 5 with the two-stage construction is also applicable to the emitter follower circuit in the foregoing embodiments 2-7.

### EMBODIMENT 12

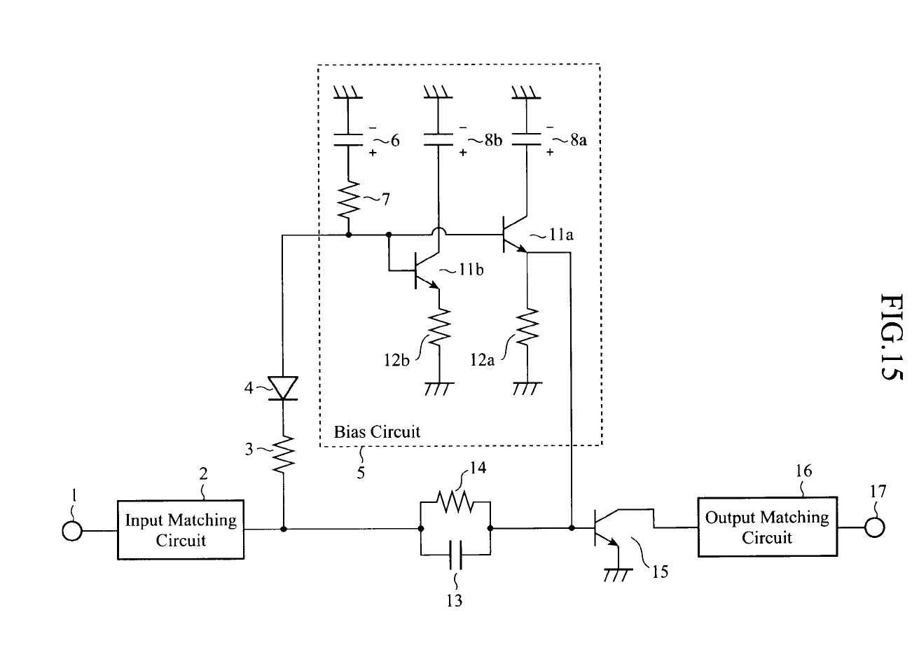

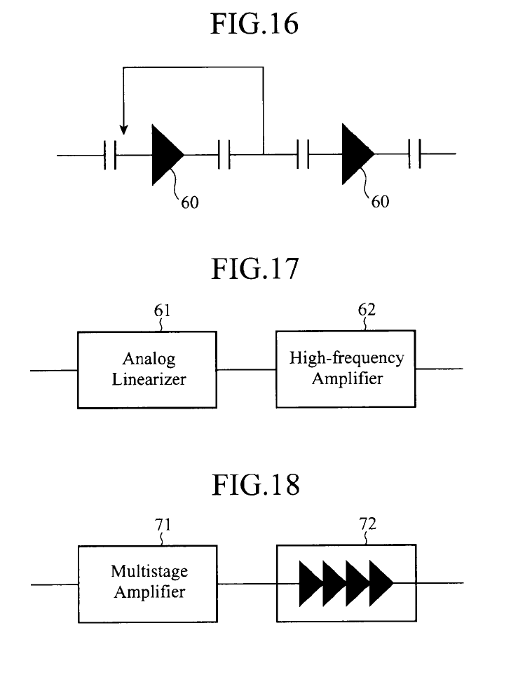

FIG. 16 is a diagram showing a configuration of a multistage amplifier having a plurality of high-frequency amplifiers of any one of the foregoing embodiments 1-11 connected in multistage

A detecting diode 4 of the high-frequency amplifiers 60 constituting the multistage amplifier of FIG. 16 receives the modulation wave signal to be input to the post-high-frequency amplifier 60 or the modulation wave signal output from the post-high-frequency amplifier 60, and detects the envelope signal of the modulation wave signal.

In this case, even if a small modulation wave signal such as that the detecting diode 4 of the foregoing embodiments 1-11 cannot detect is input, the multistage amplifier can detect the envelope signal of the modulation wave signal.

### EMBODIMENT 13

FIG. 17 is a diagram showing a configuration of a high-frequency amplifier having an analog linearizer connected in the previous stage. In FIG. 17, an analog linearizer 61 is placed before a high-frequency amplifier 62 for adjusting the gain of the modulation wave signal.

The high-frequency amplifier 62 is a high-frequency amplifier of any one of the foregoing embodiments 1-11.

When the analog linearizer 61 is placed before the high-frequency amplifier 62 as shown in FIG. 17, the analog linearizer 61 can adjust the gain of the modulation wave signal. This makes it possible to reduce the range of the gain to be adjusted by the high-frequency amplifier 62, and to improve the accuracy.

### EMBODIMENT 14

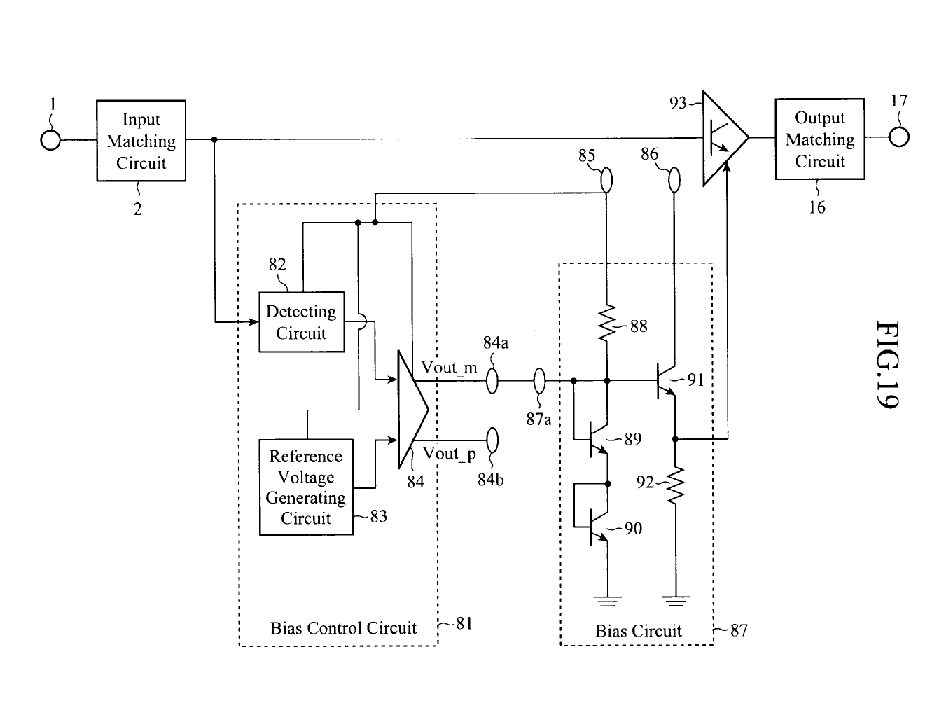

FIG. 18 is a diagram showing a configuration of a high-frequency amplifier having a multistage amplifier connected in a previous stage. In FIG. 18, a multistage amplifier 71, which is placed before a high-frequency amplifier 72, has a plurality of amplifiers connected in multistage.

The high-frequency amplifier 72 is any one of the high-frequency amplifiers of the foregoing embodiments 1-11. The gain characteristics of the high-frequency amplifier 72 are controlled in such a manner as to assume reverse characteristics of the gain characteristics of the multistage amplifier 71, and its amplifying element 15 operates as an analog linearizer.

When the multistage amplifier 71 is placed before the high-frequency amplifier 72 as shown in FIG. 18 and the gain characteristics of the high-frequency amplifier 72 are controlled in such a manner as to take the reverse characteristics of the gain characteristics of the multistage amplifier 71, the amplifying element 15 of the high-frequency amplifier 72 operates as an analog linearizer.

This offers the same advantage as the foregoing embodiment 13 without connecting a new linearizer. In addition, it offers an advantage of being able to achieve downsizing.

### EMBODIMENT 15

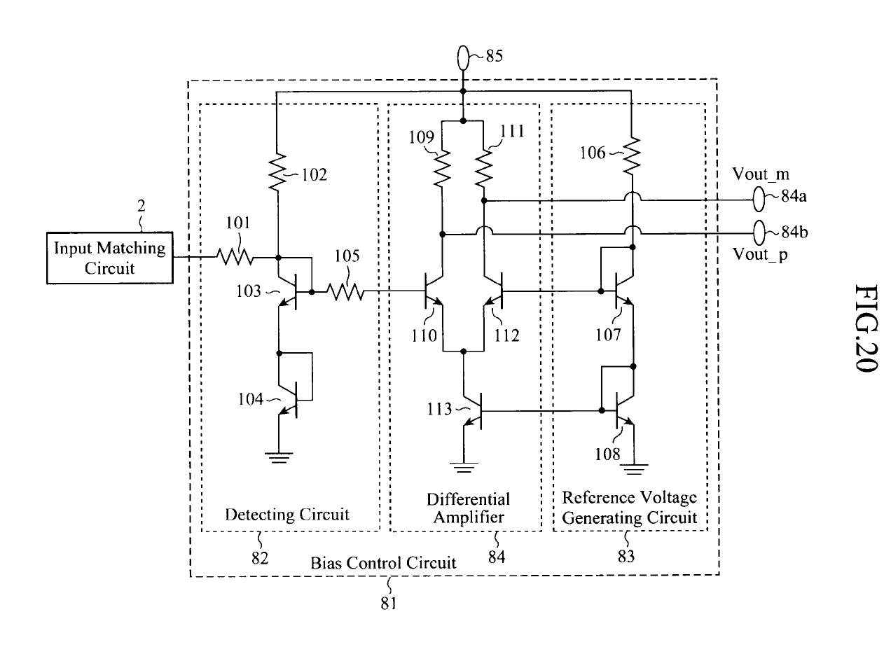

FIG. 19 is a diagram showing a configuration of a high-frequency amplifier of an embodiment 15 in accordance with the present invention. In FIG. 19, since the same reference numerals as those of FIG. 1 designate the same or like portions, their description will be omitted here.

A bias control circuit 81 comprises a detector circuit 82, a reference voltage generating circuit 83 and a differential amplifier 84, and carries out processing of controlling the bias current supplied from a bias circuit 87.

The detector circuit 82 is a circuit that is biased by a power supply 85, detects the envelope signal of the modulation wave signal input via the input terminal 1, and supplies the envelope signal to the differential amplifier 84. Incidentally, the detector circuit 82 constitutes a detecting unit.

The reference voltage generating circuit 83 is a circuit biased by the power supply 85 for generating the reference voltage and for supplying the reference voltage to the differential amplifier 84.

The differential amplifier 84, which is a comparator, is biased by the power supply 85, compares the envelope signal detected by the detector circuit 82 with the reference voltage generated by the reference voltage generating circuit 83, outputs control voltage Vout_m (first control voltage) indicating the compared result, and outputs control voltage Vout_p (second control voltage) with reverse characteristics of the control voltage Vout_m.

A control voltage output terminal 84a is a terminal of the differential amplifier 84 for outputting the control voltage Vout_m, and a control voltage output terminal 84b is a terminal of the differential amplifier 84 for outputting the control voltage Vout_p.

FIG. 19 shows an example of a high-frequency amplifier in which when the amplitude of the envelope signal increases, the bias current supplied from the bias circuit B7 to the amplifying element 93 is suppressed following the amplitude of the envelope signal. Thus, the control voltage output terminal 84a of the differential amplifier 84 is connected to the input terminal 87a of the bias circuit 87. However, in the high-frequency amplifier in which the bias current supplied from the bias circuit 87 to the amplifying element 93 increases following the amplitude of the envelope signal, the control voltage output terminal 84b of the differential amplifier 84 is connected to the input terminal 87a of the bias circuit 87.

The bias circuit 87 is a circuit that is biased in common with the bias control circuit 81 by the common power supply 85, that supplies, when its input terminal 87a is connected to the control voltage output terminal 84a of the differential amplifier 84, the base terminal of the amplifying element 93 with the bias current corresponding to the control voltage Vout_m output from the control voltage output terminal 84a of the differential amplifier 84, and that supplies, when its input terminal 87a is connected to the control voltage output terminal 84b of the differential amplifier 84, the base terminal of the amplifying element 93 with the bias current corresponding to the control voltage Vout_p output from the control voltage output terminal 84b of the differential amplifier 84.

Incidentally, the reference voltage generating circuit 83, differential amplifier 84 and bias circuit 87 constitute a bias current supplying unit.

A PN junction diode 89 of the bias circuit 87 has its base terminal and collector terminal short-circuited and connected to the input terminal 87a and to the power supply 85 via a bias resistance 88.

A PN junction diode 90 has its base terminal and collector terminal short-circuited and connected to the emitter terminal of the PN junction diode 89, and its emitter terminal connected to the ground.

An NPN bipolar transistor 91 has its base terminal connected to the input terminal 87a, its collector terminal connected to a collector power supply 86, and its emitter terminal connected to the base terminal of the amplifying element 93.

An emitter grounding resistance 92 has its first end connected to the emitter terminal of the NPN bipolar transistor 91 and its second terminal connected to the ground.

The amplifying element 93 is an element that has its gain characteristics controlled in accordance with the bias current supplied from the bias circuit 87, and amplifies the modulation wave signal input via the input terminal 1. Incidentally, the amplifying element 93 constitutes an amplifying unit.

FIG. 20 is a diagram showing a configuration of the bias control circuit 81 of the high-frequency amplifier of the embodiment 15 in accordance with the present invention.

In FIG. 20, a detection sensitivity control resistance 101 of the detector circuit 82 has its first end connected to the input matching circuit 2 and its second terminal connected to the base terminal and collector terminal of a PN junction diode 103.

In the example of FIG. 20, although the detection sensitivity control resistance 101 is placed in the detector circuit 82, it can be placed outside the detector circuit 82.

The PN junction diode 103 has its base terminal and collector terminal short-circuited and connected to the power supply 85 via a bias resistance 102.

A PN junction diode 104 has its base terminal and collector terminal short-circuited and connected to the emitter terminal of the PN junction diode 103, and its emitter terminal connected to the ground.

A detection sensitivity control resistance 105 has its first end connected to the base terminal and collector terminal of the PN junction diode 103 and its second terminal connected to the base terminal of an NPN bipolar transistor 110 of the differential amplifier 84.

In the example of FIG. 20, although the detection sensitivity control resistance 105 is placed in the detector circuit 82, it can be placed outside the detector circuit 82.

A PN junction diode 107 of the reference voltage generating circuit 83 has its base terminal and collector terminal short-circuited and connected to the power supply 85 via a bias resistance 106.

A PN junction diode 108 has its base terminal and collector terminal short-circuited and connected to the emitter terminal of the PN junction diode 107. In addition, it has its base terminal and collector terminal connected to the base terminal of an NPN bipolar transistor 113 of the differential amplifier 84, and its emitter terminal connected to the ground.

The NPN bipolar transistor 110 of the differential amplifier 84 has its base terminal connected to the detection sensitivity control resistance 105, its collector terminal connected to the power supply 85 via a bias resistance 109 and to the control voltage output terminal 84b, and its emitter terminal connected to the emitter terminal of an NPN bipolar transistor 112 and to the collector terminal of the NPN bipolar transistor 113.

The NPN bipolar transistor 112 has its base terminal connected to the base terminal and collector terminal of the PN junction diode 107 of the reference voltage generating circuit 83, its collector terminal connected to the power supply 85 via a bias resistance 111 and to the control voltage output terminal 84a, and its emitter terminal connected to the emitter terminal of the NPN bipolar transistor 110 and the collector terminal of the NPN bipolar transistor 113.

The NPN bipolar transistor 113 has its base terminal connected to the base terminal and collector terminal of the PN junction diode 108 of the reference voltage generating circuit 83, its collector terminal connected to the emitter terminal of the NPN bipolar transistor 110 and to the emitter terminal of the NPN bipolar transistor 112, and its emitter terminal connected to the ground.

Next, the operation will be described.

The detector circuit 82, reference voltage generating circuit 83, differential amplifier 84 and bias circuit 87 are biased by the common power supply 85.

When the modulation wave signal, which is the high-frequency signal, is input via the input terminal 1, the amplifying element 93 amplifies the modulation wave signal and outputs the amplified modulation wave signal.

On this occasion, the detector circuit 82 of the bias control circuit 81 follows the amplitude of the envelope signal of the modulation wave signal input via the input terminal 1, and detects the amplitude of the envelope signal.

The detector circuit 82, detecting the amplitude of the envelope signal, applies the bias voltage corresponding to the amplitude of the envelope signal to the base terminal of the NPN bipolar transistor 110 of the differential amplifier 84 via the detection sensitivity control resistance 105.

Incidentally, when the amplitude of the envelope signal increases, a detection current flowing through the PN junction diode 103 and PN junction diode 104 is generated, which reduces the voltage at the base terminal and collector terminal of the PN junction diode 103 (the bias voltage corresponding to the amplitude of the envelope signal).

Receiving the bias from the power supply 85, the reference voltage generating circuit 83 generates constant bias voltage (reference voltage) independent of the amplitude of the envelope signal, and applies the bias voltage to the base terminal of the NPN bipolar transistor 112 of the differential amplifier 84.

The differential amplifier 84 compares the bias voltage applied from the detector circuit 82 with the bias voltage applied from the reference voltage generating circuit 83, outputs the control voltage Vout_m indicating the compared result from the control voltage output terminal 84a, and outputs the control voltage Vout_p with the reverse characteristics of the control voltage Vout_m from the control voltage output terminal 84b.

More specifically, the operation is as follows.

The current flowing through the NPN bipolar transistor 113 of the differential amplifier 84 is the sum of the currents flowing through the NPN bipolar transistor 110 and NPN bipolar transistor 112, and the sum of the currents is constant.

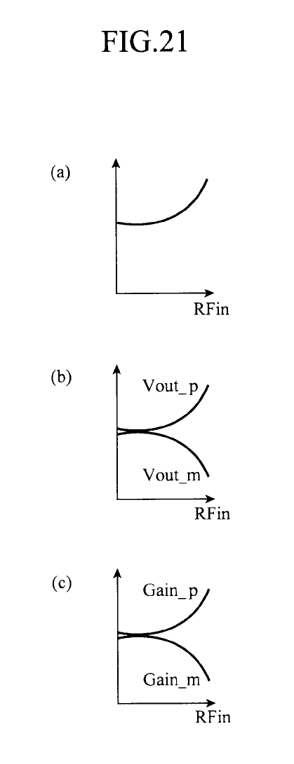

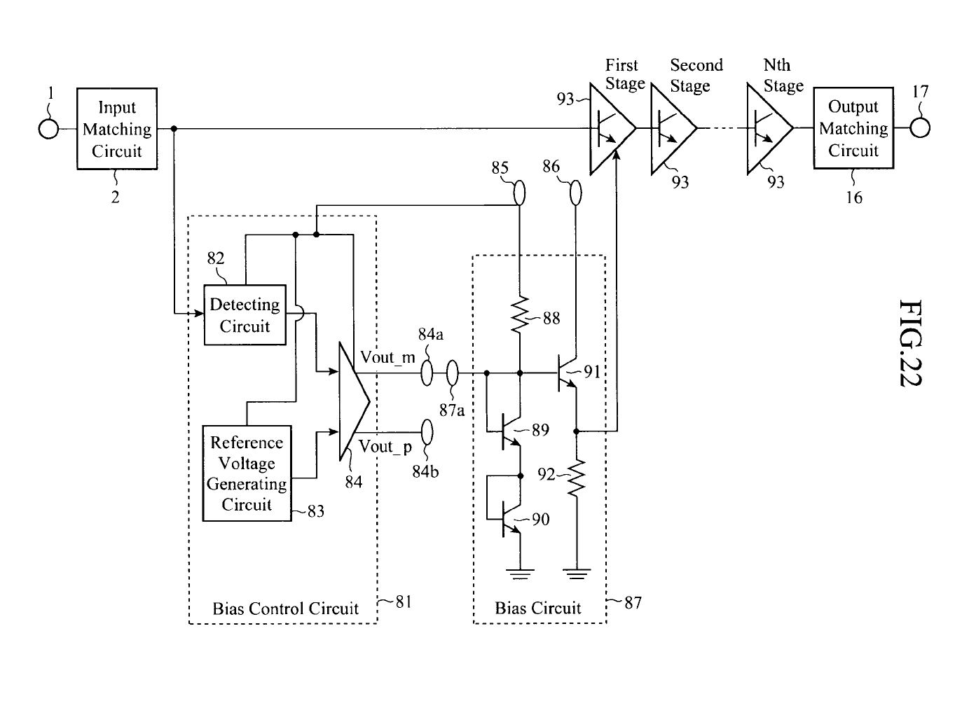

When the amplitude of the envelope signal increases as shown in FIG. 21(a), and the voltage applied from the detector circuit 82 to the base terminal of the NPN bipolar transistor 110 reduces, the current flowing through the NPN bipolar transistor 110 reduces, thereby increasing the current flowing through the NPN bipolar transistor 112.

In this case, the control voltage Vout_p, the output voltage from the control voltage output terminal 84b connected to the collector terminal of the NPN bipolar transistor 110, increases as shown in FIG. 21(b). In contrast, the control voltage Vout_m, the output voltage from the control voltage output terminal 84a connected to the collector terminal of the NPN bipolar transistor 112, reduces as shown in FIG. 21(b).

In other words, when the amplitude of the envelope signal increases, it operates in such a manner that the control voltage Vout_p, the output voltage from the control voltage output terminal 84b, increases, and that the control voltage Vout_m, the output voltage from the control voltage output terminal 84a, decreases.

The bias circuit 87 has its input terminal 87a connected to the control voltage output terminal 84a or control voltage output terminal 84b of the differential amplifier 84 (in the example of FIG. 19, it is connected to the control voltage output terminal 84a), and supplies the base terminal of the amplifying element 93 with the bias current corresponding to the control voltage Vout_m or control voltage Vout_p output from the control voltage output terminal 84a or control voltage output terminal 84b.

Thus, when the input terminal 87a is connected to the control voltage output terminal 84a of the differential amplifier 84, and the control voltage Vout m output from the control voltage output terminal 84a reduces owing to the increase of the amplitude of the envelope signal, the NPN bipolar transistor 91 of the bias circuit 87 operates in such a manner as to reduce the bias current supplied to the base terminal of the amplifying element 93.

On the other hand, when the input terminal 87a is connected to the control voltage output terminal 84a of the differential amplifier 84, and the control voltage Vout_p output from the control voltage output terminal 84b increases owing to the increase of the amplitude of the envelope signal, the NPN bipolar transistor 91 operates in such a manner as to increase the bias current supplied to the base terminal of the amplifying element 93.

More specifically, the operation is as follows.

When the control voltage output terminal 84a of the differential amplifier 84 is connected to the input terminal 87a of the bias circuit 87, the bias current supplied to the base terminal of the amplifying element 93 is generated by the current supplied from the power supply 85 to the base terminal of the NPN bipolar transistor 91. In this case, when the amplitude of the envelope signal of the modulation wave signal input via the input terminal 1 increases and hence the control voltage Vout_m output from the control voltage output terminal 84a of the differential amplifier 84 reduces, the current supplied from the power supply 85 to the base terminal of the NPN bipolar transistor 91 reduces by the amount of the reduction of the control voltage Vout_m, thereby reducing the bias current supplied to the base terminal of the amplifying element 93.

Thus, the bias current increases or decreases in accordance with the amplitude of the envelope signal of the modulation wave signal input via the input terminal 1 so that the bias current supplied from the bias circuit 87 to the base terminal of the amplifying element 93 is suppressed with the increase of the amplitude of the envelope signal. As a result, the gain Gain_m of the amplifying element 93 decreases as shown in FIG. 21(c).

Likewise, when the control voltage output terminal 84b of the differential amplifier 84 is connected to the input terminal 87a of the bias circuit 87, the bias current supplied to the base terminal of the amplifying element 93 is generated by the current supplied from the power supply 85 to the base terminal of the NPN bipolar transistor 91 . In this case, when the amplitude of the envelope signal of the modulation wave signal input via the input terminal 1 increases and hence the control voltage Vout_p output from the control voltage output terminal 84b of the differential amplifier 84 increases, the current supplied from the power supply 85 to the base terminal of the NPN bipolar transistor 91 increases by the amount of the increase of the control voltage Vout_p, thereby increasing the bias current supplied to the base terminal of the amplifying element 93.

Thus, the bias current increases or decreases in accordance with the amplitude of the envelope signal of the modulation wave signal input via the input terminal 1 so that the bias current supplied from the bias circuit 87 to the base terminal of the amplifying element 93 is increased with the increase the amplitude of the envelope signal. As a result, the gain Gain_p of the amplifying element 93 increases as shown in FIG. 21(c).

As is clear from the above, according to the present embodiment 15, it is configured in such a manner that it comprises the reference voltage generating circuit 83 for generating the reference voltage; the differential amplifier 84 for comparing the reference voltage generated by the reference voltage generating circuit B3 with the envelope signal detected by the detector circuit 82, for outputting the control voltage Vout_m indicating the compared result from the control voltage output terminal 84a, and for outputting the control voltage Vout_p with the reverse characteristics of the characteristics of the control voltage Vout_m from the control voltage output terminal 84b; and the bias circuit 87 that has its input terminal 87a connected to one of the control voltage output terminals 84a and 84b of the differential amplifier 84, and supplies the base terminal of the amplifying element 93 with the bias current corresponding to the control voltage Vout_m or control voltage Vout_p, and that when the amplitude of the envelope signal increases, the bias current supplied from the bias circuit 87 to the amplifying element 93 is reduced or increased following the amplitude of the envelope signal. Accordingly, it offers an advantage of being able to obviate the need for the power supply and the DC element capacitance of the detector circuit, and to prevent the deterioration of the distortion characteristics involved in the gain reduction near the saturation even if the modulation wave signal with the high crest factor is input.

### EMBODIMENT 16

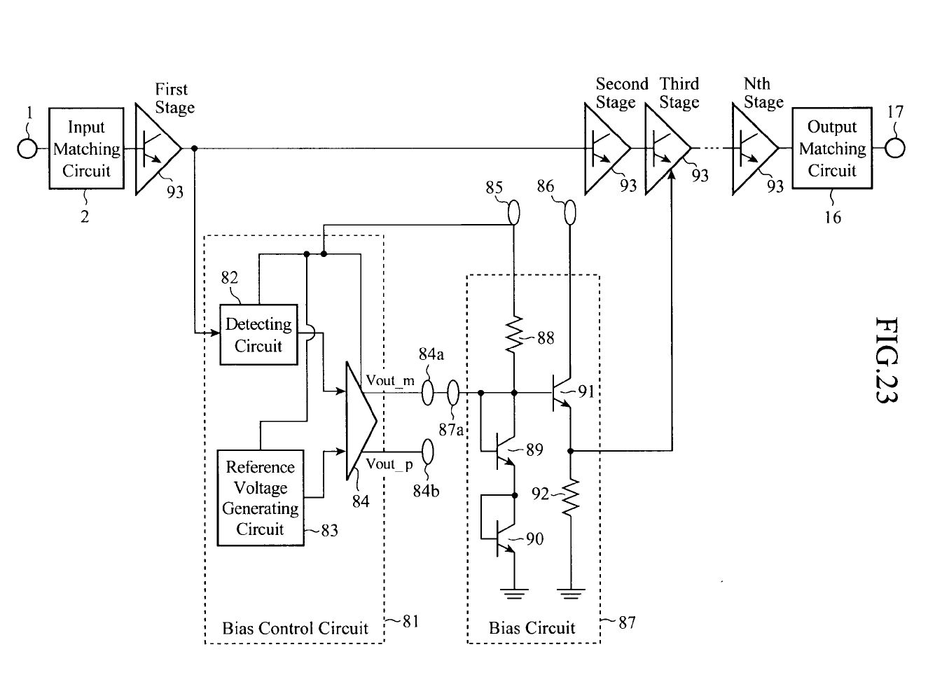

FIG. 22 is a diagram showing a configuration of a high-frequency amplifier of an embodiment 16 in accordance with the present invention.

Although the foregoing embodiment 15 shows the high-frequency amplifier with a single stage consisting of the amplifying element 93, another configuration is also possible which includes a plurality of amplifying elements 93 connected in multistage as shown in FIG. 22.

FIG. 22 shows an example in which N amplifying elements 93 are connected in multistage, and the bias circuit 87 supplies the bias current to the first amplifying element 93. However, another configuration is also possible in which the bias circuit 87 supplies the bias current to any one of the amplifying elements 93.

The gain characteristics of the amplifying element 93 to which the bias circuit 87 supplies the bias current are controlled in accordance with the reverse characteristics of the gain characteristics of the multistage amplifier, and hence the amplifying element 93 operates as an analog linearizer.

As for bias currents of the amplifying elements 93 to which the bias circuit 87 does not supply the bias current, although FIG. 22 does not show any of them because they are not limited in particular, some bias currents are supplied.

### EMBODIMENT 17

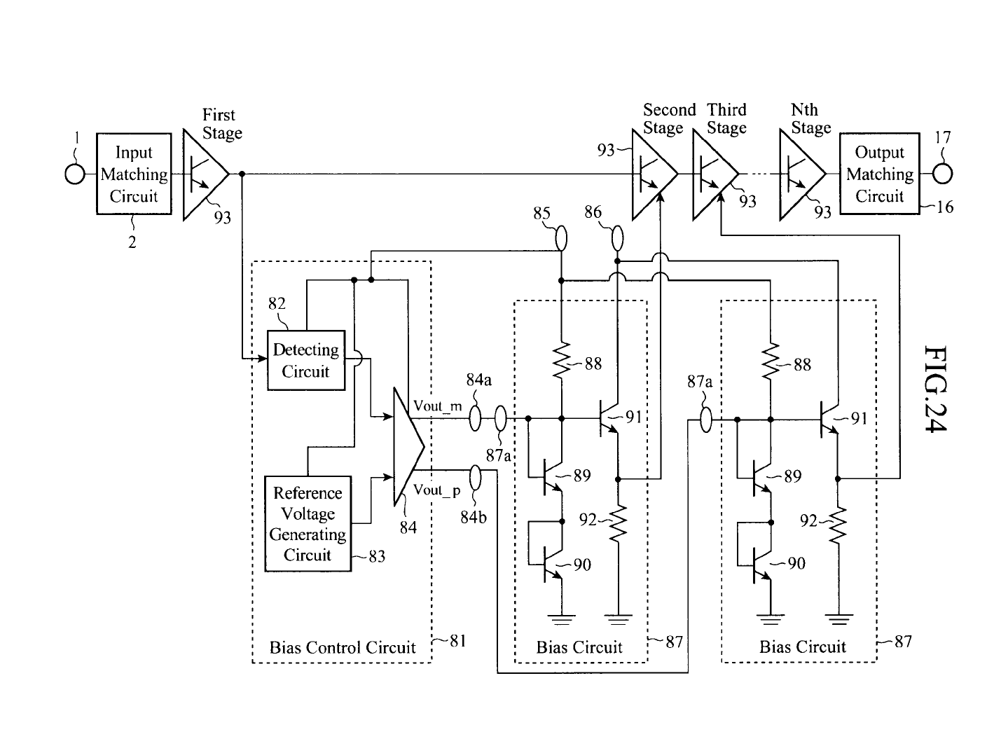

FIG. 23 is a diagram showing a configuration of a high-frequency amplifier of an embodiment 17 in accordance with the present invention.

The foregoing embodiment 16 shows a case where the bias circuit 87 supplies the bias current to any one of the N amplifying elements 93. As for the modulation wave signal the detector circuit 82 detects, however, it can be a modulation wave signal that is output from or input to any one of the amplifying elements 93.

More specifically, the detector circuit 82 detects the envelope signal of the modulation wave signal input to any one of the amplifying elements 93 or that of the modulation wave signal output from any one of the amplifying elements 93.

FIG. 23 shows an example in which the detector circuit 82 detects the envelope signal of the modulation wave signal output from the first-stage amplifying element 93.

In addition, in the example of FIG. 23, the bias circuit 87 supplies the bias current to the third-stage amplifying element 93. In the present embodiment 17, however, another configuration is also possible in which the bias circuit 87 supplies the bias current to any one of the amplifying elements 93.

### EMBODIMENT 18

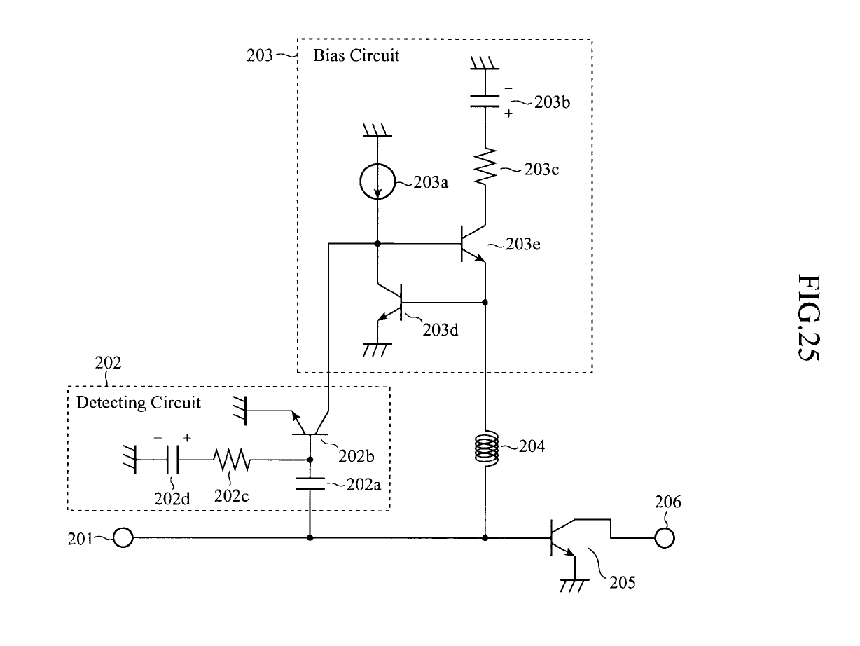

FIG. 24 is a diagram showing a configuration of a high-frequency amplifier of an embodiment 18 in accordance with the present invention.

The foregoing embodiment 16 shows a case where the bias circuit 87 supplies the bias current to anyone of the N amplifying elements 93. As for the modulation wave signal the detector circuit 82 detects, however, it can be a modulation wave signal that is output from or input to anyone of the amplifying elements 93.

More specifically, the detector circuit 82 detects the envelope signal of the modulation wave signal input to any one of the amplifying elements 93 or that of the modulation wave signal output from any one of the amplifying elements 93.

FIG. 24 shows an example in which the detector circuit 82 detects the envelope signal of the modulation wave signal output from the first-stage amplifying element 93.

Although the foregoing embodiment 17 shows a case where the bias circuit 87 has its input terminal 87a connected to the control voltage output terminal 84a of the differential amplifier 84, another configuration that includes two bias circuits 87 as shown in FIG. 24 is also possible. The first bias circuit 87 has its input terminal 87a connected to the control voltage output terminal 84a of the differential amplifier 84, and supplies the bias current to the base terminal of the second-stage amplifying element 93 (pre-stage amplifying element), for example.

The second bias circuit 87 has its input terminal 87a connected to the control voltage output terminal 84b of the differential amplifier 84, and supplies the bias current to the base terminal of the third-stage amplifying element 93 (post-stage amplifying element), for example.

Thus, when the amplitude of the envelope signal increases, the bias current supplied to the base terminal of the second-stage amplifying element 93 is decreased following the amplitude of the envelope signal, which reduces the gain of the second-stage amplifying element 93. In addition, the bias current supplied to the base terminal of the third-stage amplifying element 93 is increased, and the gain of the third-stage amplifying element 93 is increased.

### INDUSTRIAL APPLICABILITY

As described above, the high-frequency amplifier in accordance with the present invention is suitable for a device that must follow the modulation speed of the modulation wave, and must prevent the deterioration of the distortion characteristics involved in the gain reduction near the saturation even if the modulation wave signal with the high crest factor is input.

What is claimed is:

1. A high-frequency amplifier comprising:
a detecting unit for detecting an envelope signal of a modulation wave signal;
a bias current supplying unit for supplying a bias current corresponding to the amplitude of the envelope signal detected by the detecting unit; and
an amplifying unit for amplifying the modulation wave signal with its gain characteristics being controlled in accordance with the bias current supplied from the bias current supplying unit, wherein
the detecting unit and the bias current supplying unit are biased by a common power supply, and the bias current supplied from the bias current supplying unit to the amplifying unit is increased or decreased following the amplitude of the envelope signal when the amplitude of the envelope signal increases.

2. The high-frequency amplifier according to claim 1, wherein
when the amplitude of the envelope signal increases, the bias current supplying unit suppresses, following the amplitude of the envelope signal, the bias current it supplies to the amplifying unit.

3. The high-frequency amplifier according to claim 2, wherein
the detecting unit comprises a diode having its anode connected to the power supply.

4. The high-frequency amplifier according to claim 2, wherein
the detecting unit comprises an antiparallel diode pair having two diodes connected in parallel with their directions being opposite to each other, and wherein
when the amplitude of the envelope signal increases, the bias current supplying unit suppresses the bias current it supplies to the amplifying unit, and when the amplitude of the envelope signal further increases to such a level that causes a current to flow through the two diodes, the bias current supplying unit increases the bias current it supplies to the amplifying unit.

5. The high-frequency amplifier according to claim 2, wherein
the detecting unit comprises an antiparallel diode pair having two diodes connected in opposite directions to each other, the two diodes having their input terminals of the modulation wave signal connected to resistances, respectively.

6. The high-frequency amplifier according to claim 1, wherein
when the amplitude of the envelope signal increases, the bias current supplying unit increases, following the amplitude of the envelope signal, the bias current it supplies to the amplifying unit.

7. The high-frequency amplifier according to claim 6, wherein
the detecting unit comprises a diode having its cathode connected to the power supply.

8. The high-frequency amplifier according to claim 1, wherein
the detecting unit has a three-stage construction comprising one diode and two transistors.

9. The high-frequency amplifier according to claim 1, further comprising a variable resistance connected in series or in parallel with the detecting unit.

10. The high-frequency amplifier according to claim 1, further comprising a capacitor connected in parallel with the detecting unit.

11. The high-frequency amplifier according to claim 1, wherein the bias current supplying unit comprises:
a diode having its base terminal and collector terminal connected to the detecting unit and to the power supply;
a first resistance having its first end connected to an emitter terminal of the diode and its second terminal connected to a ground;
a transistor having its base terminal connected to the detecting unit, its collector terminal connected to a collector power supply, and its emitter terminal connected to the amplifying unit; and
a second resistance having its first end connected to an emitter terminal of the transistor, and its second terminal connected to the ground, and wherein
the first resistance and the second resistance have an equal resistance value.

12. The high-frequency amplifier according to claim 1, wherein the bias current supplying unit comprises two-stage emitter follower circuits.

13. A high-frequency amplifier comprising a plurality of high-frequency amplifiers as defined in claim 1, which are connected in multistage, wherein the detecting unit receives a modulation wave signal input to a post-high-frequency amplifier or receives a modulation wave signal output from the post-high-frequency amplifier, and detects an envelope signal of the modulation wave signal.

14. The high-frequency amplifier according to claim 1, wherein the detecting unit and the amplifying unit are supplied with the modulation wave signal having its gain adjusted through an analog linearizer.

15. The high-frequency amplifier according to claim 1, wherein
when a multistage amplifier having a plurality of amplifiers connected in multistage is placed at a previous stage, the amplifying unit has its gain characteristics controlled in a manner as to have reverse characteristics of gain characteristics of the multistage amplifier, and the amplifying unit operates as an analog linearizer.

16. The high-frequency amplifier according to claim 1, wherein the bias current supplying unit comprises:
a reference voltage generating circuit for generating a reference voltage;
a differential amplifier for comparing the reference voltage generated by the reference voltage generating circuit with the envelope signal detected by the detecting unit, for outputting a first control voltage indicating the compared result, and for outputting a second control voltage having reverse characteristics of characteristics of the first control voltage; and
a bias circuit for supplying a bias current corresponding to the first control voltage or second control voltage output from the differential amplifier, and wherein
when the amplitude of the envelope signal increases, the bias current supplying unit increases or decreases, following the amplitude of the envelope signal, the bias current it supplies to the amplifying unit.

17. The high-frequency amplifier according to claim 16, wherein when the amplifying units are connected in multistage, the bias current supplying unit supplies the bias current to any one of the amplifying units.

18. The high-frequency amplifier according to claim 17, wherein the detecting unit detects the envelope signal of the modulation wave signal supplied to any one of the amplifying units or the envelope signal of the modulation wave signal output from any one of the amplifying units.

19. The high-frequency amplifier according to claim 16, wherein when the amplifying units are connected in multistage, the detecting unit detects the envelope signal of the modulation wave signal supplied to any one of the amplifying units or the envelope signal of the modulation wave signal output from any one of the amplifying units, and the bias current supplying unit supplies the bias current to any two of the amplifying units connected in multistage.

20. The high-frequency amplifier according to claim 19, wherein when the amplitude of the envelope signal increases, the bias current supplying unit suppresses, following the amplitude of the envelope signal, the bias current supplied to a pre-stage amplifying unit between the amplifying units which are supplied with the bias current from the bias current supplying unit, and wherein when the amplitude of the envelope signal increases, the bias current supplying unit increases, following the amplitude of the envelope signal, the bias current supplied to a post-stage amplifying unit.
